(19) United States
(12) Patent Application Publication
(10) Pub. No.: US 2011/0041890 A1
(43) Pub. Date: Feb. 24, 2011

(54) HIGH-EFFICIENCY, HIGH CURRENT SOLAR CELL AND SOLAR MODULE

(76) Inventor: James R. Sheats, San Jose, CA (US)

Correspondence Address: Director of IP, 5521 Hellyer Avenue, San Jose, CA, 95138, US

(21) Appl. No.: 12/743,775

(22) PCT Filed: Nov. 19, 2008
(86) PCT No.: PCT/US08/84050

§ 371 Date: Oct. 20, 2010

Related U.S. Application Data
(60) Provisional application No. 60/989,114, filed on Nov. 19, 2007.

(51) Int. Cl. H01L 31/042

(52) U.S. Cl. 136/244

(57) ABSTRACT

Methods and devices are provided for high-efficiency solar cells. In one embodiment, a high current photovoltaic apparatus is provided comprising of a thin-film absorber layer solar module of arbitrary size having an electrical output with a current of greater than about 2 amperes when the module is under AM1.5G illumination at 25° C. Optionally, the current is at least about 5 amperes. Optionally, the current is at least about 15 amperes. Optionally, the current is at least about 50 amperes. Optionally, the current is at least about 100 amperes.

### FIELD OF THE INVENTION

This invention relates to optoelectronic devices and more particularly to high current solar devices.

### BACKGROUND OF THE INVENTION

Optoelectronic devices can convert radiant energy into electrical energy or vice versa. These devices generally include an active layer sandwiched between two electrodes, sometimes referred to as the front and back electrodes, at least one of which is typically transparent. The active layer typically includes one or more semiconductor materials. In a light-emitting device, e.g., a light-emitting diode (LED), a voltage applied between the two electrodes causes a current to flow through the active layer. The current causes the active layer to emit light. In a photovoltaic device, e.g., a solar cell, the active layer absorbs energy from light and converts this energy to electrical energy exhibited as a voltage and/or current between the two electrodes. Large scale arrays of such solar cells can potentially replace conventional electrical generating plants that rely on the burning of fossil fuels. However, in order for solar cells to provide a cost-effective alternative to conventional electric power generation the cost per watt generated must be competitive with current electric grid rates. Currently, there are a number of technical challenges to attaining this goal.

Most conventional solar cells rely on silicon-based semiconductors. In a typical silicon-based solar cell, a layer of n-type silicon (sometimes referred to as the emitter layer) is deposited on a layer of p-type silicon. Radiation absorbed proximate the junction between the p-type and n-type layers generates electrons and holes. The electrons are collected by an electrode in contact with the n-type layer and the holes are collected by an electrode in contact with the p-type layer. Since light must reach the junction, at least one of the electrodes must be at least partially transparent. Many current solar cell designs use a transparent conductive oxide (TCO) such as indium tin oxide (ITO) as a transparent electrode.

A further problem associated with existing solar fabrication techniques arises from the fact that individual optoelectronic devices produce only a relatively small voltage. Thus, it is often necessary to electrically connect several devices together in series in order to obtain higher voltages in order to take advantage of the efficiencies associated with high voltage, low current operation (e.g. power transmission through a circuit using relatively higher voltage, which reduces resistive losses that would otherwise occur during power transmission through a circuit using relatively higher current).

Several designs have been previously developed to interconnect solar cells into modules. For example, early photovoltaic module manufacturers attempted to use a “shingling” approach to interconnect solar cells, with the bottom of one cell placed on the top edge of the next, similar to the way shingles are laid on a roof. Unfortunately the solder and silicon wafer materials were not compatible. The differing rates of thermal expansion between silicon and solder and the rigidity of the wafers caused premature failure of the solder joints with temperature cycling.

A further problem associated with series interconnection of optoelectronic devices arises from the high electrical resistivity associated with the TCO used in the transparent electrode. The high resistivity restricts the size of the individual cells that are connected in series. To carry the current from one cell to the next the transparent electrode is often augmented with a conductive grid of busses and fingers formed on a TCO layer. However, the fingers and busses produce shadowing that reduces the overall efficiency of the cell. In order for the efficiency losses from resistance and shadowing to be small, the cells must be relatively small. Consequently, a large number of small cells must be connected together, which requires a large number of interconnects and more space between cells. Arrays of large numbers of small cells are relatively difficult and expensive to manufacture. Further, with flexible solar modules, shingling is also disadvantageous in that the interconnection of a large number of shingles is relatively complex, time-consuming and labor-intensive, and therefore costly during the module installation process.

To overcome this, optoelectronic devices have been developed with electrically isolated conductive contacts that pass through the cell from a transparent “front” electrode through the active layer and the “back” electrode to an electrically isolated electrode located beneath the back electrode. U.S. Pat. No. 3,903,427 describes an example of the use of such contacts in silicon-based solar cells. Although this technique does reduce resistive losses and can improve the overall efficiency of solar cell devices, the costs of silicon-based solar cells remains high due to the vacuum processing techniques used in fabricating the cells as well as the expense of thick, single-crystal silicon wafers.

This has led solar cell researchers and manufacturers to develop different types of solar cells that can be fabricated less expensively and on a larger scale than conventional silicon-based solar cells. Examples of such solar cells include cells with active absorber layers comprised of silicon (e.g. for amorphous, micro-crystalline, or polycrystalline silicon cells), organic oligomers or polymers (for organic solar cells), bi-layers or interpenetrating layers or inorganic and organic materials (for hybrid organic/inorganic solar cells), dye-sensitized titania nanoparticles in a liquid or gel-based electrolyte (for Graetzel cells), copper-indium-gallium-selenium (for CIG solar cells), cells whose active layer is comprised of CdSe, CdTe, and combinations of the above, where the active materials are present in any of several forms including but not limited to bulk materials, micro-particles, nano-particles, or quantum dots. Many of these types of cells can be fabricated on flexible substrates (e.g., stainless steel foil). Although these types of active layers can be manufactured in non-vacuum environments, the intra-cell and inter-cell electrical connection typically requires vacuum deposition of one or more metal conducting layers.

For example FIG. 1A illustrates a portion of a prior art solar cell array 1. The array 1 is manufactured on a flexible insulating substrate 2. Series interconnect holes 4 are formed through the substrate 2 and a bottom electrode layer 6 is deposited, e.g., by sputtering, on a front surface of the substrate and on sidewalls of the holes. Current collection holes 8 are then formed through the bottom electrode and substrate at selected locations and one or more semiconductor layers 10 are then deposited over the bottom electrode 6 and the sidewalls of the series interconnect holes 4 and current collection holes 8. A transparent conductor layer 12 is then deposited using a shadow mask that covers the series interconnect holes 4. A second metal layer 14 is then deposited over the backside of the substrate 2 making electrical contact with the transparent conductor layer 12 through the current collection holes and providing series interconnection between cells through the series interconnect holes. Laser scribing 16, 18 on the front side and the back side separates the monolithic device into individual cells.

FIG. 1B depicts another prior art array 20 that is a variation on the array 1. The array 20 is also manufactured on a flexible insulating substrate 22. Series interconnect holes 24 are formed through the substrate 22 and a bottom electrode layer 26 is deposited, e.g., by sputtering, on front and back surfaces of the substrate 22 and on sidewalls of the holes 24. Current collection holes 28 are then formed through the bottom electrode and substrate at selected locations and one or more semiconductor layers 30 and a transparent conducting layer 32 are then deposited over the bottom electrode 26 on the front side and on the sidewalls of the series interconnect holes 24 and current collection holes 28. A second metal layer 34 is then deposited over the backside of the substrate 22 using a shadow mask that covers everything except the current collection holes 28 making electrical contact with the transparent conductor layer 32. Laser scribing 36,38 on the front side and the back side separates the monolithic device into individual cells.

There are two significant drawbacks to manufacturing solar cell arrays as shown in FIGS. 1A-1B. First, the metal layers are deposited by sputtering, which is a vacuum technique. Vacuum techniques are relatively, slow, difficult and expensive to implement in large scale roll-to-roll manufacturing environments. Secondly, the manufacturing process produces a monolithic array and sorting of individual cells for yield is not possible. This means that only a few bad cells can ruin the array and therefore increase cost. In addition, the manufacturing process is very sensitive to the morphology and size of the holes. Since the front to back electrical conduction is along the sidewall of the hole, making the holes larger does not increase conductivity enough. Thus, there is a narrow process window, which can add to the cost of manufacture and reduce yield of usable devices. Furthermore, although vacuum deposition is practical for amorphous silicon semiconductor layers, it is impractical for highly efficient solar cells based, e.g., on combinations of Copper, Indium, Gallium and Selenium or Sulfur, sometimes referred to as CIGS cells. To deposit a CIGS layer, three or four elements must be deposited in a precisely controlled ratio. This is extremely difficult to achieve using vacuum deposition processes.

Thus, there is a need in the art, for an optoelectronic device architecture that overcomes the above disadvantages and a corresponding method to manufacture such cells.

### SUMMARY OF THE INVENTION

Embodiments of the present invention address at least some of the drawbacks set forth above. The present invention provides for the use insulating materials in via holes formed in a photovoltaic device using an improved structure that overcomes the disadvantage of the know devices. At least some of these and other objectives described herein will be met by various embodiments of the present invention.

In one embodiment of the present invention, a high current photovoltaic apparatus is provided comprising of a thin-film absorber layer solar module of arbitrary size having an electrical output with a current of greater than about 2 amperes when the module is under AM1.5G illumination at 25° C. Optionally, the current is at least about 5 amperes. Optionally, the current is at least about 15 amperes. Optionally, the current is at least about 50 amperes. Optionally, the current is at least about 100 amperes.

Embodiments herein may also be modified to include one or more of the following. In one embodiment, the module includes one or more thin-film cells sized to an area sufficiently large to generate a current greater than about 2 amperes under AM1.5G illumination and wherein less than about 15% of a top side surface area of the one or more cells comprises of an opaque conductor, irrespective of cell size. Optionally, less than about 10% of a top side surface area of the one or more cells comprises of the opaque conductor. Optionally, less than about 8% of a top side surface area of the one or more cells comprises of the opaque conductor. Optionally, less than about 7.5% of a top side surface area of the one or more cells comprises of the opaque conductor. Optionally, less than about 5% of a top side surface area of the one or more cells comprises of the opaque conductor. Optionally, less than about 2.5% of a top side surface area of the one or more cells comprises of the opaque conductor. Optionally, the module includes one or more thin-film cells sized to an area sufficiently large to generate a current greater than about 5 amperes under AM1.5G illumination. Optionally, one or more cells have an active area of at least 97.5% of total cell size. Optionally, one or more cells have an active area of at least 95% of total cell size. Optionally, one or more cells have an active area of at least 92.5% of total cell size. Optionally, one or more cells have an active area of at least 90% of total cell size. Optionally, one or more cells have an active area of at least 85% of total cell size. Optionally, the bottom electrode of one cell has an area of sufficient ampacity to carry current from an upstream cell electrically coupled to the cell. Optionally, the bottom electrode has sufficient thickness of metal foil to carry at least 5 amperes of current. Optionally, the bottom electrode has sufficient thickness of aluminum foil to carry at least 5 amperes of current. Optionally, the bottom electrode has sufficient thickness of aluminum foil of about 25 to about 125 microns to carry at least 5 amperes of current.

Embodiments herein may also be modified to include one or more of the following. The bottom electrode may be comprised of a sputtered material is deposited directly on a highly conductive foil. Optionally, a thin-film bottom electrode (such as but not limited to an Mo layer) is directly deposited on top of a highly conductive (Copper, bronze, aluminum, metal, or other metal coated) foil . . . to achieve current-carrying capacity for that end of the cell too. The latter differentiates some embodiments from thin-film-on-foil embodiments where the foil is a plastic (or an insulator or a bare stainless steel foil with insufficient current-carrying capacity). Optionally, thin-film bottom electrode of one cell is laser welded to a highly conductive backside foil of another cell to achieve current-carrying capacity between from one cell to another cell. Optionally for each cell, a thin-film bottom electrode of one cell is electrically coupled to a highly conductive backside foil of another cell to achieve current-carrying capacity between from one cell to another cell. Optionally, for each cell, a thin-film bottom electrode is directly deposited or placed on top of a highly conductive foil to achieve current-carrying capacity between from one cell to another cell. Optionally, resistive losses in a transparent conductor of the one or more cells is minimized through the use of vias filled with electrical conductors, wherein the vias are dispersed over the one or more cells to couple the transparent conductor to a high ampacity, bulk electrical conductor below a photovoltaic absorber layer in the one or more cells. Optionally, the vias are distributed in a regular, repeating pattern. Optionally, the vias have fingers that are distributed in a regular, repeating pattern. Optionally, the vias are distributed in an irregular pattern. Optionally, the vias have fingers that are distributed in an irregular pattern. Optionally, the vias have depth between about 10 microns to about 300 microns. Optionally, the vias have depth between about 150 microns to about 250 microns.

Embodiments herein may also be modified to include one or more of the following. In one embodiment, a ratio of opaque conductor area to exposed active area photovoltaic material is between about 1:9 to about 1:39. Optionally, increased cell size does not substantially increase cell shading due to increased ampacity of a backside electrical conductor to handle at least 5 amperes of current. Optionally, the module includes one or more thin-film cells, wherein each of the one or more solar cells includes a backside electrical conductor having an average thickness of about 50 to about 100 microns. Optionally, the module includes one or more thin-film cells, wherein each of the one or more solar cells includes a backside electrical conductor having an average thickness of about 100 to about 800 microns. Optionally, the solar module includes one or more thin-film photovoltaic cells each sized to have a top side total area of about 10000 mm2 or more to generate a current of greater than about 2 amperes when under AM1.5G illumination. Optionally, the solar module includes one or more thin-film photovoltaic cells each sized to have a top side area of about 21000 mm2 or more to generate a current of greater than about 5 amperes when under AM1.5G illumination. Optionally, the solar module includes one or more thin-film photovoltaic cells each sized to have a top side area of about 21000 mm2 to about 24000 mm2 to generate a current of greater than about 5 amperes when under AM1.5G illumination. Optionally, the module has a low voltage electrical output with a voltage less than about 40 volts. Optionally, the module has a low voltage electrical output with a voltage less than about 20 volts. Optionally, the module has a low voltage electrical output with a voltage less than about 10 volts. Optionally, the module has a low voltage electrical output with a voltage less than about 1 volt. Optionally, the module has electrical output with a power greater than about 200 watts. Optionally, the module has electrical output with a power greater than about 100 watts. Optionally, the module has electrical output with a power greater than about 50 watts.

Embodiments herein may also be modified to include one or more of the following. In one embodiment, the module provides the electrical output without using monolithically integrated photovoltaic cells. Optionally, the solar module includes only a single photovoltaic cell. Optionally, the single photovoltaic cell has an area of 0.5 m2 or more. Optionally, the single photovoltaic cell has an area of 1 m2 or more. Optionally, the single photovoltaic cell has an area of 2 m2 or more. Optionally, the single photovoltaic cell has an area of 3 m2 or more. Optionally, resistive losses encountered in the transparent conductor is less than 5% before charge is collected by a conductive finger or conductive via. Optionally, resistive losses encountered in the transparent conductor is less than 3% before charge is collected by a conductive finger or conductive via. Optionally, the module includes about 1 to about 200 cells, wherein the module generates about 200 Watts (+/−5%) at more than 2 amperes current when under AM1.5G illumination. Optionally, the module includes about 1 to about 168 cells. Optionally, the module includes about 1 to about 100 cells. Optionally, the module includes about 42 to about 84 cells. Optionally, the module includes about 1 to about 200 cells, wherein the module generates about 140 Watts (+/−5%) at more than 2 amperes current when under AM1.5G illumination. Optionally, the module includes about 1 to about 168 cells. Optionally, the module includes about 1 to about 100 cells. Optionally, the module includes about 42 to about 84 cells. Optionally, the module includes about 3 to about 30 strings of about 3 to about 30 cells in each string, which in total generates about 200 Watts (+/−5%) with more than 2 amperes current at AM1.5G illumination. Optionally, the module includes about 10 to about 18 strings of about 5 to about 8 cells in each string, which in total generates about 200 Watts (+/−5%) with more than 2 amperes current at AM1.5G illumination. Optionally, the module includes about 10 to about 18 strings of about 5 to about 8 cells in each string, which in total generates about 140 Watts (+/−5%) with more than 2 amperes current at AM1.5G illumination. Optionally, the module includes about 14 strings of 6 cells which in total generates about 200 Watts (+/−5%) with more than 5 amperes current at AM1.5G illumination. Optionally, the module includes about 14 strings of 6 cells which in total generates about 140 Watts (+/−5%) with more than 5 amperes current at AM1.5G illumination. Optionally, the module has electrical connectors for wiring the module in a landscape configuration. Optionally, the module has electrical connectors for wiring the module in a portrait configuration. Optionally, the absorber layer comprises of an inorganic material. Optionally, the absorber layer comprises of an organic material. Optionally, the module comprises a flexible module. Optionally, the module comprises a glass-glass module. Optionally, the module comprises a glass-foil module.

In another embodiment of the present invention, an apparatus is provided comprising a high current solar module of arbitrary size using any type of absorber material and having an electrical output having a current of greater than about 15 amperes when the module is under AM1.5G illumination. The module may include one or more solar cells sized to an area sufficiently large to generate a current greater than about 15 amperes under AM1.5G illumination, wherein resistive losses in a transparent conductor of the cells is minimized through the use of vias filled with electrical conductors, wherein the vias are dispersed over the cell to couple the transparent conductor on the one or more cells to a high ampacity, bulk electrical conductor below a photovoltaic absorber layer in the one or more cells.

In yet another embodiment of the present invention, a photovoltaic system is provided comprising of a plurality of thin film solar modules electrically coupled together. The total system voltage of the plurality of solar modules in series does not exceed about 1000V, wherein total system current is about 2 amperes or more; wherein total system power output is about 2000 watts or more due to the high current output of the thin film modules. Optionally, total system power output is about 3000 watts or more. Optionally, total system power output is about 5000 watts or more. Optionally, total system power output is about 10000 watts or more. Optionally, total system power output is about 100000 watts or more. Optionally, total system power output is about 1000000 watts or more.

Embodiments herein may also be modified to include one or more of the following. One embodiment comprise of a module string of thin-film base modules that includes between about 15 modules to about 22 modules. Optionally in one embodiment, a module string of thin-film base modules that includes between about 10 modules to about 60 modules. Optionally, total voltage of the plurality of solar modules in series does not exceed about 600V. Optionally, total system current is about 5 amperes or more. Optionally, electrical connectors between modules sized to have an ampacity to carry total system current is about 5 amperes or more. Optionally, the system may include an inverter wherein the size of the cell is selected to so that electrical current from the cells under AM1.5G illumination is such that that total power output and total voltage from the plurality of modules is within an optimal range for power and voltage for optimum inverter performance. Optionally, the module includes about 1 to about 200 cells, wherein the module generates about 200 Watts (+/−5%) at more than 2 amperes current when under AM1.5G illumination. Optionally, the module includes about 1 to about 168 cells. Optionally, the module includes about 1 to about 100 cells. Optionally, the module includes about 42 to about 84 cells. Optionally, the modules each include one or more thin-film cells sized to an area sufficiently large to generate a current greater than about 2 amperes under AM1.5G illumination and wherein less than about 15% of a top side surface area of the one or more cells comprises of an opaque conductor, irregardless of cell size. Optionally, less than about 10% of a top side surface area of the one or more cells comprises of the opaque conductor. Optionally, less than about 7.5% of a top side surface area of the one or more cells comprises of the opaque conductor. Optionally, less than about 5% of a top side surface area of the one or more cells comprises of the opaque conductor. Optionally, less than about 2.5% of a top side surface area of the one or more cells comprises of the opaque conductor. Optionally, optimum inverter performance is based on a total system voltage at 1000V. Optionally, optimum inverter performance is based on a total system voltage at 600V. Optionally, the system includes an inverter coupled to multiple module strings in parallel. Optionally, the modules are flexible modules. Optionally, the modules are rigid modules. Optionally, the modules are oriented in a landscape configuration. Optionally, the modules are oriented in a portrait configuration.

In yet another embodiment of the present invention, a method is provided comprising: forming high current photovoltaic cells by: increasing cell size to a size sufficient to generate at least 2 amperes at AM1.5G illumination without covering more than 15% of the top side area with opaque conductors; increasing backside conductor ampacity and increasing the number of electrical connections from a top side transparent conductor to the backside conductor. Optionally, a plurality of vias are formed in the cells, wherein the vias are filled with electrical conductors which couple the transparent conductor to the backside conductor. Optionally, less than about 10% of the top side surface area of a cell comprises of the opaque conductor, irregardless of cell size. Optionally, less than about 7.5% of the top side surface area of a cell comprises of the opaque conductor, irregardless of cell size. Optionally, less than about 5% of the top side surface area of a cell comprises of the opaque conductor, irregardless of cell size. Optionally, less than about 2.5% of the top side surface area of a cell comprises of the opaque conductor, irregardless of cell size. Optionally, the one or more photovoltaic cells are sized to an area sufficiently large to generate a current greater than about 5 amperes under AM1.5G illumination. Optionally, increasing cell size increases backside conductor thickness without substantially changing top side finger or busbar density. Optionally, a method of forming a flexible high current module comprised of one or more high current cells produced as set forth herein. Optionally, a method of forming a rigid high current module comprised of one or more high current cells produced as set forth herein.

A further understanding of the nature and advantages of the invention will become apparent by reference to the remaining portions of the specification and drawings.

### BRIEF DESCRIPTION OF THE DRAWINGS

FIG. 1A is a cross-sectional schematic diagram of a portion of a solar cell array according to the prior art.

FIG. 1B is a cross-sectional schematic diagram of a portion of an alternative solar cell array according to the prior art.

FIG. 2A is a vertical cross-sectional schematic diagram of a portion of an array of optoelectronic devices according to an embodiment of the present invention.

FIG. 2B is a plan view schematic diagram of the array of FIG. 1A.

FIGS. 2C-2E are plan view schematic diagrams illustrating alternative trace patterns for an optoelectronic device of the type shown in FIGS. 2A-2B.

FIG. 3 is a sequence of schematic diagrams illustrating fabrication of an array of optoelectronic devices according to an embodiment of the present invention.

FIG. 4 is an exploded view schematic diagram illustrating fabrication of an array of optoelectronic devices according to an alternative embodiment of the present invention.

FIG. 5A is an exploded view schematic diagram illustrating fabrication of an array of optoelectronic devices according to another alternative embodiment of the present invention.

FIG. 5B is a cross-sectional schematic diagram illustrating a portion of the array of FIG. 5A.

FIGS. 6A-6I are cross-sectional schematic diagrams illustrating formation of electrical contacts according to embodiments of the present invention.

FIGS. 7-9 show various trace patterns according to embodiments of the present invention.

FIG. 10 shows a via hole forming devices according to embodiments of the present invention.

FIGS. 11A-11D show a method for forming an insulating layer according to embodiments of the present invention.

FIGS. 12A-12C show a method for forming an insulating layer according to embodiments of the present invention.

FIGS. 13A-13C show a method for forming an insulating layer according to embodiments of the present invention.

FIGS. 14A-14C show a method for forming an insulating layer according to embodiments of the present invention.

FIGS. 15A-15C show a method for forming an insulating layer according to embodiments of the present invention.

FIGS. 16A-16B show a method for forming an insulating layer according to embodiments of the present invention.

FIGS. 16A-16B show a method for forming an insulating layer according to embodiments of the present invention.

FIGS. 17 and 18 show cross-sectional views of solar cells according to embodiments of the present invention.

FIGS. 19 and 20 show top down views of solar cells according to embodiments of the present invention.

FIGS. 21 and 22 show top down views of solar modules according to embodiments of the present invention.

FIGS. 23 and 24 show views of systems according to embodiments of the present invention.

FIGS. 25 and 26 show cross-sectional views of solar cells according to embodiments of the present invention.

FIGS. 27 through 29 show side views of strain relief elements according to embodiments of the present invention.

### DESCRIPTION OF THE SPECIFIC EMBODIMENTS

It is to be understood that both the foregoing general description and the following detailed description are exemplary and explanatory only and are not restrictive of the invention, as claimed. It may be noted that, as used in the specification and the appended claims, the singular forms “a”, “an” and “the” include plural referents unless the context clearly dictates otherwise. Thus, for example, reference to “a material” may include mixtures of materials, reference to “a compound” may include multiple compounds, and the like. References cited herein are hereby incorporated by reference in their entirety, except to the extent that they conflict with teachings explicitly set forth in this specification.

In this specification and in the claims which follow, reference will be made to a number of terms which shall be defined to have the following meanings:

“Optional” or “optionally” means that the subsequently described circumstance may or may not occur, so that the description includes instances where the circumstance occurs and instances where it does not. For example, if a device optionally contains a feature for a barrier film, this means that the barrier film feature may or may not be present, and, thus, the description includes both structures wherein a device possesses the barrier film feature and structures wherein the barrier film feature is not present.

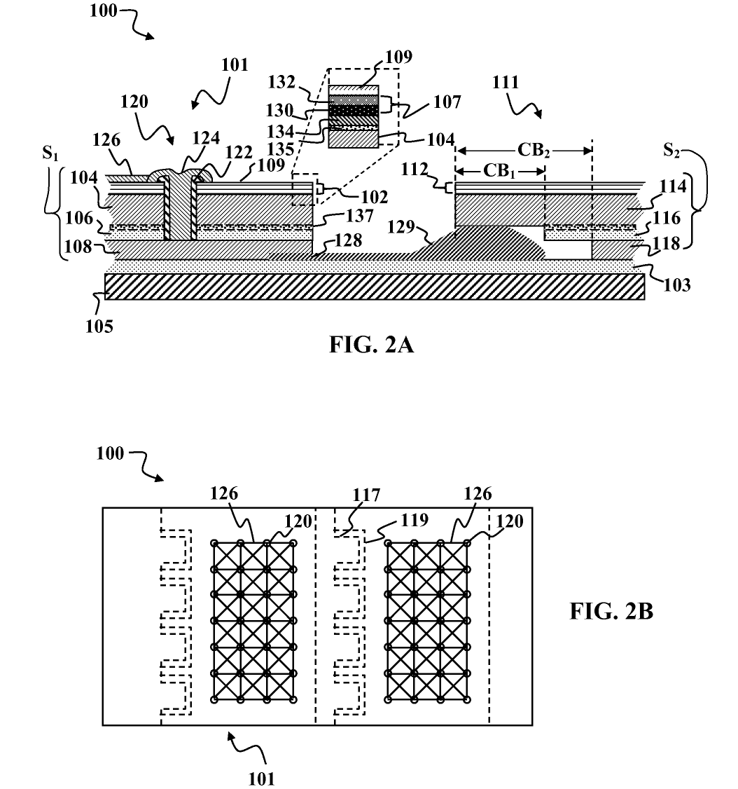

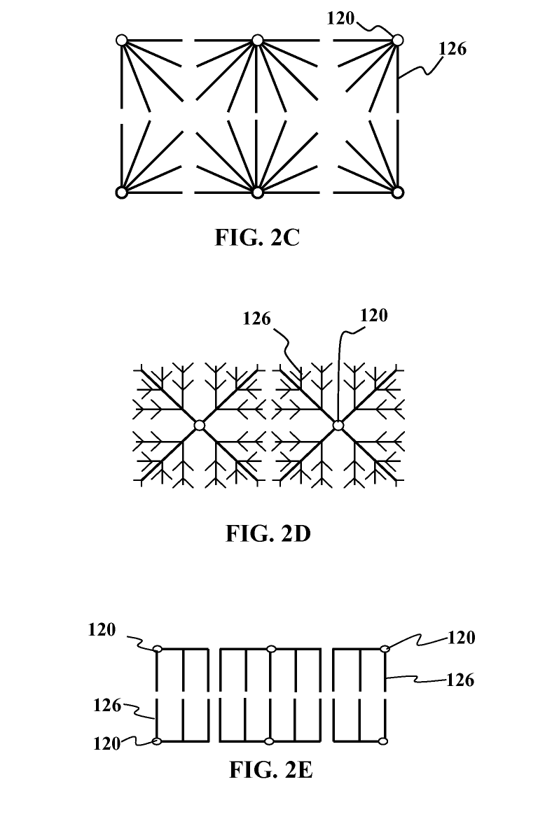

FIGS. 2A-2B illustrates an array 100 of optoelectronic devices according to an embodiment of the present invention. In some embodiments, this may be considered a series interconnections in an array 100 of optoelectronic devices. The array 100 includes a first device module 101 and a second device module 111. The device modules 101, 111 may be photovoltaic devices, such as solar cells, or light-emitting devices, such as light-emitting diodes. In a preferred embodiment, the device modules 101, 111 are solar cells. The first and second device modules 101, 111 are attached to an insulating carrier substrate 103, which may be made of a plastic material such as polyethylene terephthalate (PET), e.g., about 50 microns thick. The carrier substrate 103 may, in turn, be attached to a thicker structural membrane 105, e.g., made of a polymeric roofing membrane material such as thermoplastic polyolefin (TPO) or ethylene propylene diene monomer (EPDM), to facilitate installing the array 100 on an outdoor location such as a roof.

The device modules 101, 111, which may be about 4 inches in length and 12 inches wide, may be cut from a much longer sheet containing several layers that are laminated together. Each device module 101, 111 generally include a device layer 102, 112 in contact with a bottom electrode 104, 114 and an insulating layer 106, 116 between the bottom electrode 104, 114 and a conductive back plane 108, 118. It should be understood that in some embodiments of the present invention, the back plane 108, 118 may be described as a backside top electrode 108, 118. The bottom electrodes 104, 114, insulating layers 106, 116 and back planes 108, 118 for substrates S₁, S₂ support the device layers 102, 112

In contrast to prior art cells, where the substrates are formed by depositing thin metal layers on an insulating substrate, embodiments of the present invention utilize substrates S₁, S₂ based on flexible bulk conducting materials, such as foils. Although bulk materials such as foils are thicker than prior art vacuum deposited metal layers they can also be cheaper, more readily available and easier to work with. Preferably, at least the bottom electrode 104, 114 is made of a metal foil, such as aluminum foil. Alternatively, copper, stainless steel, titanium, molybdenum or other suitable metal foils may be used. By way of example, the bottom electrodes 104, 114 and back planes 108, 118 may be made of aluminum foil about 1 micron to about 200 microns thick, preferably about 25 microns to about 100 microns thick; the insulating layers 106, 116 may be made of a plastic foil material, such as polyethylene terephthalate (PET) about 1 micron to about 200 microns thick, preferably about 10 microns to about 50 microns thick. Optionally, back planes 108, 118 may be comprised of stainless steel, copper, titanium, molybdenum, steel, aluminum, copper-plated or coated versions of any of the foregoing, silver plated or coated versions of any of the aforementioned, gold-plated or coated versions of the foregoing, or combinations thereof. In one embodiment, among others, the bottom electrode 104,114, insulating layer 106, 116 and back plane 108, 118 are laminated together to form the starting substrates S₁, S₂. Although foils may be used for both the bottom electrode 104, 114 and the back plane 108, 118 it is also possible to use a mesh grid on the back of the insulating layer 106, 116 as a back plane. Such a grid may be printed onto the back of the insulating layer 106, 116 using a conductive ink or paint. One example, among others, of a suitable conductive paint or ink is Dow Corning® PI-2000 Highly Conductive Silver Ink available from Dow Corning Corporation of Midland Mich. Dow Corning® is a registered trademark of Dow Corning Corporation of Midland Mich. Furthermore, the insulating layer 106, 116 may be formed by anodizing a surface of a foil used for the bottom electrode 104, 114 or back plane 108, 118 or both, or by applying an insulating coating by spraying, coating, or printing techniques known in the art.

The device layers 102, 112 generally include an active layer 107 disposed between a transparent conductive layer 109 and the bottom electrode 104. By way of example, the device layers 102, 112 may be about 2 microns thick. At least the first device 101 includes one or more electrical contacts 120 between the transparent conducting layer 109 and the back plane 108. The electrical contacts 120 are formed through the transparent conducting layer 109, the active layer 107, the bottom electrode 104 and the insulating layer 106. The electrical contacts 120 provide an electrically conductive path between the transparent conducting layer 109 and the back plane 108. The electrical contacts 120 are electrically isolated from the active layer 107, the bottom electrode 104 and the insulating layer 106.

The contacts 120 may each include a via formed through the active layer 107, the transparent conducting layer 109, the bottom electrode 104 and the insulating layer 106. Each via may be about 0.1 millimeters to about 1.5 millimeters, preferably 0.5 millimeters to about 1 millimeter in diameter. The vias may be formed by punching or by drilling, for example by mechanical, laser or electron beam drilling, or by a combination of these techniques. An insulating material 122 coats sidewalls of the via such that a channel is formed through the insulating material 122 to the back plane 108. The insulating material 122 may have a thickness between about 1 micron and about 200 microns, preferably between about 10 microns and about 200 microns.

The insulating material 122 should preferably be at least 10 microns thick to ensure complete coverage of the exposed conductive surfaces behind it. The insulating material 122 may be formed by a variety of printing techniques, including for example inkjet printing or dispensing through an annular nozzle. A plug 124 made of an electrically conductive material at least partially fills the channel and makes electrical contact between the transparent conducting layer 109 and the back plane 108. The electrically conductive material may similarly be printed. A suitable material and method, for example, is inkjet printing of solder (called “solderjet” by Microfab, Inc., Plano, Tex., which sells equipment useful for this purpose). Printing of conductive adhesive materials known in the art for electronics packaging may also be used, provided time is allowed subsequently for removal of solvent which may or may not be present, and curing. The plug 124 may have a diameter between about 5 microns and about 500 microns, preferably between about 25 and about 100 microns.

By way of nonlimiting example, in other embodiments, the device layers 102, 112 may be about 2 microns thick, the bottom electrodes 104, 114 may be made of aluminum foil about 100 microns thick; the insulating layers 106, 116 may be made of a plastic material, such as polyethylene terephthalate (PET) about 25 microns thick; and the backside top electrodes 108, 118 may be made of aluminum foil about 25 microns thick. The device layers 102, 112 may include an active layer 107 disposed between a transparent conductive layer 109 and the bottom electrode 104. In such an embodiment, at least the first device 101 includes one or more electrical contacts 120 between the transparent conducting layer 109 and the backside top electrode 108. The electrical contacts 120 are formed through the transparent conducting layer 109, the active layer 107, the bottom electrode 104 and the insulating layer 106. The electrical contacts 120 provide an electrically conductive path between the transparent conducting layer 109 and the backside top electrode 108. The electrical contacts 120 are electrically isolated from the active layer 107, the bottom electrode 104 and the insulating layer 106.

The formation of good contacts between the conductive plug 124 and the substrate 108 may be assisted by the use of other interface-forming techniques such as ultrasonic welding. An example of a useful technique is the formation of gold stud-bumps, as described for example by J. Jay Wimer in “3-D Chip Scale with Lead-Free Processes” in Semiconductor International, Oct. 1, 2003, which is incorporated herein by reference. Ordinary solders or conductive inks or adhesives may be printed on top of the stud bump.

In forming the vias, it is important to avoid making shorting connections between the top electrode 109 and the bottom electrode 104. Therefore, mechanical cutting techniques such as drilling or punching may be advantageously supplemented by laser ablative removal of a small volume of material near the lip of the via, a few microns deep and a few microns wide. Alternatively, a chemical etching process may be used to remove the transparent conductor over a diameter slightly greater than the via. The etching can be localized, e.g., by printing drops of etchant in the appropriate places using inkjet printing or stencil printing.

A further method for avoiding shorts involves deposition of a thin layer of insulating material on top of the active layer 107 prior to deposition of the transparent conducting layer 109. This insulating layer is preferably several microns thick, and may be in the range of 1 to 100 microns. Since it is deposited only over the area where a via is to be formed (and slightly beyond the borders of the via), its presence does not interfere with the operation of the optoelectronic device. In some embodiments of the present invention, the layer may be similar to structures described in U.S. patent application Ser. No. 10/810,072 to Karl Pichler, filed Mar. 25, 2004, which is hereby incorporated by reference. When a hole is drilled or punched through this structure, there is a layer of insulator between the transparent conducting layer 109 and the bottom electrode 104 which may be relatively thick compared to these layers and to the precision of mechanical cutting processes, so that no short can occur.

The material for this layer can be any convenient insulator, preferably one that can be digitally (e.g. inkjet) printed. Thermoplastic polymers such as Nylon PA6 (melting point (m.p.) 223° C.), acetal (m.p. 165° C.), PBT (structurally similar to PET but with a butyl group replacing the ethyl group) (m.p. 217° C.), and polypropylene (m.p. 165° C.), are examples which by no means exhaust the list of useful materials. These materials may also be used for the insulating layer 122. While inkjet printing is a desirable way to form the insulator islands, other methods of printing or deposition (including conventional photolithography) are also within the scope of the invention.

In forming the vias, it is useful to fabricate the optoelectronic device in at least two initially separate elements, with one comprised of the insulating layer 106, the bottom electrode 104 and the layers 102 above it, and the second comprised of the back plane 108. These two elements are then laminated together after the vias have been formed through the composite structure 106/104/102, but before the vias are filled. After this lamination and via formation, the back plane 108 is laminated to the composite, and the vias are filled as described above.

Although jet-printed solders or conductive adhesives comprise useful materials for forming the conductive via plug 124, it is also possible to form this plug by mechanical means. Thus, for example, a wire of suitable diameter may be placed in the via, forced into contact with the back plane 108, and cut off at the desired height to form the plug 124, in a manner analogous to the formation of gold stud bumps. Alternatively a pre-formed pin of this size can be placed into the hole by a robotic arm. Such pins or wires can be held in place, and their electrical connection to the substrate assisted or assured, by the printing of a very thin layer of conductive adhesive prior to placement of the pin. In this way the problem of long drying time for a thick plug of conductive adhesive is eliminated. The pin can have tips or serrations on it which punch slightly into the back plane 108, further assisting contact. Such pins may be provided with insulation already present, as in the case of insulated wire or coated wire (e.g. by vapor deposition or oxidation). They can be placed in the via before the application of the insulating material, making it easier to introduce this material.

If the pin is made of a suitably hard metal, and has a slightly tapered tip, it may be used to form the via during the punching step. Instead of using a punch or drill, the pin is inserted into the composite 106/104/102, to a depth such that the tip just penetrates the bottom; then when the substrate 108 is laminated to this composite, the tip penetrates slightly into it and forms a good contact. These pins may be injected into the unpunched substrate by, for example, mechanical pressure or air pressure directed through a tube into which the pin just fits.

One or more conductive traces 126, e.g., made of Al, Ni, or Ag, may be disposed on the transparent conducting layer 109 in electrical contact with the electrically conductive material 124. As shown in FIG. 2B, the traces 126 may interconnect multiple contacts 120 to reduce the overall sheet resistance. By way of example, the contacts 120 may be spaced about 1 centimeter apart from one another with the traces 126 connecting each contact with its nearest neighbor or in some cases to the transparent conductor surrounding it. Preferably, the number, width and spacing of the traces 126 is chosen such that the contacts 120 and traces 126 cover less than about 1% of the surface of the device module 101. The traces 126 may have a width between about 1 micron and about 200 microns, preferably between about 5 microns and about 50 microns. The traces 126 may be separated by center-to-center distances between about 0.1 millimeter and about 10 millimeters, preferably between about 0.5 millimeter and about 2 millimeters. Wider lines require a larger separation in order to avoid excessive shadowing loss. A variety of patterns or orientations for the traces 126 may be used so long as the lines are approximately equidistant from each other (e.g., to within a factor of two). An alternative pattern in which the traces 126 fan out from the contacts 120 is depicted in FIG. 2C. In another alternative pattern, shown in FIG. 2D, the traces 126 form a “watershed” pattern, in which thinner traces 126 branch out from thicker traces that radiate from the contacts 120. In yet another alternative pattern, shown in FIG. 2E, the traces 126 form a rectangular pattern from the contacts 120. It should be understood that in some embodiments of the present invention, the vertical lines may be thinner than the horizontal lines. The number of traces 126 connected to each contact may be more or less than the number shown in FIG. 2E. Some embodiments may have one more, two more, three more, or the like. The trace patterns depicted in the examples shown in FIG. 2B, FIG. 2C, FIG. 2D, and FIG. 2E are for the purpose of illustration and do not limit the possible trace patterns that may be used in embodiments of the present invention. Note that since the conductive back planes 108, 118 carry electrical current from one device module to the next the conductive traces 126 can include “fingers” while avoiding thick “busses”. This reduces the amount of shadowing due to the busses and also provides a more aesthetically pleasing appearance to the device array 100.

Fabricating the device modules 101, 111 on substrates S₁, S₂ made of relatively thick, highly conductive, flexible bulk conductor bottom electrodes 104, 114 and backplanes 108, 118 and forming insulated electrical contracts 120 through the transparent conducting layer 109, the active layer 130, the bottom electrodes 104, 114 and the insulating layer 106, 116 allows the device modules 101, 111 to be relatively large. Consequently the array 100 can be made of fewer device modules requiring fewer series interconnections compared to prior art arrays. For example, the device modules 101, 111 may be between about 1 centimeter and about 30 centimeters long and between about 1 and about 30 centimeters wide. Smaller cells (e.g., less than 1 centimeter long and/or 1 centimeter wide) may also be made as desired.

Note that since the back planes 108, 118 carry electric current from one device module to the next, the pattern of traces 126 need not contain thick busses, as used in the prior art for this purpose. Instead, the pattern of traces 126 need only provide sufficiently conductive “fingers” to carry current to the contacts 120. In the absence of busses, a greater portion of the active layers 102, 112 is exposed, which enhances efficiency. In addition, a pattern of traces 126 without busses can be more aesthetically pleasing.

Electrical contact between the back plane 108 of the first device module 101 and the bottom electrode 114 of the second device module 111 may be implemented by cutting back the back plane 118 and insulating layer 116 of the second device module to expose a portion of the bottom electrode 114. FIG. 2B illustrates an example of one way, among others, for cutting back the back plane 118 and insulating layer 116. Specifically, notches 117 may be formed in an edge of the insulating layer 116. The notches 117 align with similar, but slightly larger notches 119 in the back plane 118. The alignment of the notches 117, 119 exposes portions of the bottom electrode 114 of the second device module 111.

Electrical contact may be made between the back plane 108 of the first device module 101 and the exposed portion of the bottom electrode 114 of the second device module 111 in a number of different ways. For example, as shown in FIG. 2A, thin conducting layer 128 may be disposed over a portion of the carrier substrate 103 in a pattern that aligns with the notches 117, 119.

The thin conducting layer may be, e.g., a conductive (filled) polymer or silver ink. The conducting layer can be extremely thin, e.g., about 1 micron thick. A general criteria for determining the minimum thickness of the thin conducting layer 128 is that the fractional power p=(J/V)ρ(Lₒ²/d) dissipated in this layer is about 10⁻⁴ or less, where J is the current density, V is the voltage, Lₒ is the length of the thin conductive layer 128 (roughly the width of the gap between the first and second device modules) and ρ and d are respectively the resistivity and the thickness of the thin conductive layer 128. In that case the loss of power from this source is far less than 1% of the power being generated, and is negligible. By way of numerical example, for many applications (J/V) is roughly 0.06 A/Vcm². If Lₒ=400 microns=0.04 cm then p is approximately equal to 10⁻⁴ (ρ/d). Thus, even if the resistivity ρ is about 10⁻⁵ Ωcm (which is about ten times less than for a good bulk conductor),), the criterion can be satisfied with d less than about 1 micron (10⁻⁴ cm) thick. Thus, even a relatively resistive polymer conductor of almost any plausible printable thickness will work.

The first device module 101 may be attached to the carrier substrate 103 such that the back plane 108 makes electrical contact with the thin conducting layer 128 while leaving a portion of the thin conducting layer 128 exposed. Electrical contact may then be made between the exposed portion of the thin conducting layer 128 and the exposed portion of the bottom electrode 114 of the second device module 111. For example, a bump of conductive material 129 (e.g., more conductive adhesive) may be placed on the thin conducting layer 128 at a location aligned with the exposed portion of the bottom electrode 114. The bump of conductive material 129 is sufficiently tall as to make contact with the exposed portion of the bottom electrode 114 when the second device module 111 is attached to the carrier substrate. The dimensions of the notches 117, 119 may be chosen so that there is essentially no possibility that the thin conducting layer 128 will make undesired contact with the back plane 118 of the second device module 111. For example, the edge of the bottom electrode 114 may be cut back with respect to the insulating layer 116 by an amount of cutback CB₁ of about 400 microns. The back plane 118 may be cut back with respect to the insulating layer 116 by an amount CB₂ that is significantly larger than CB₁.

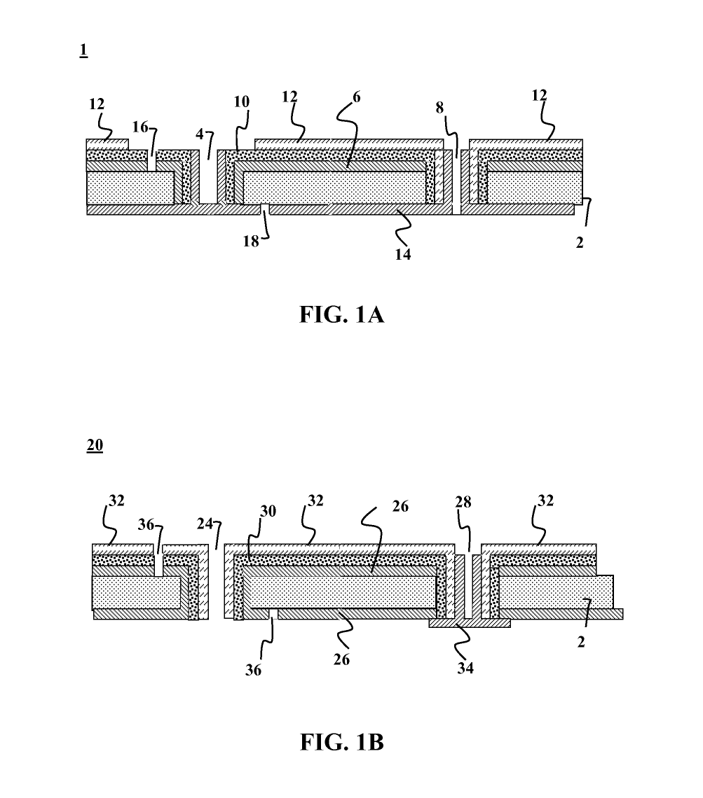

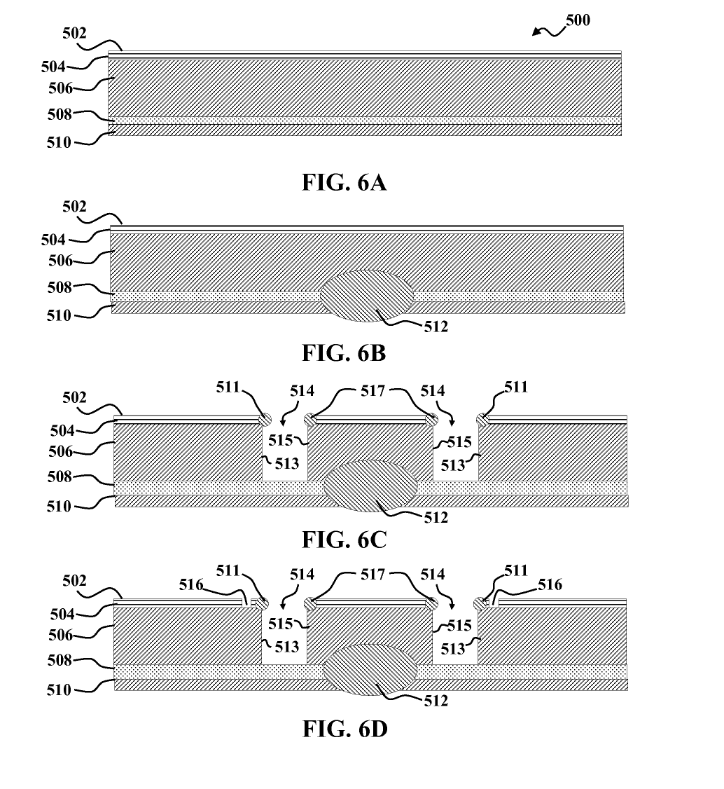

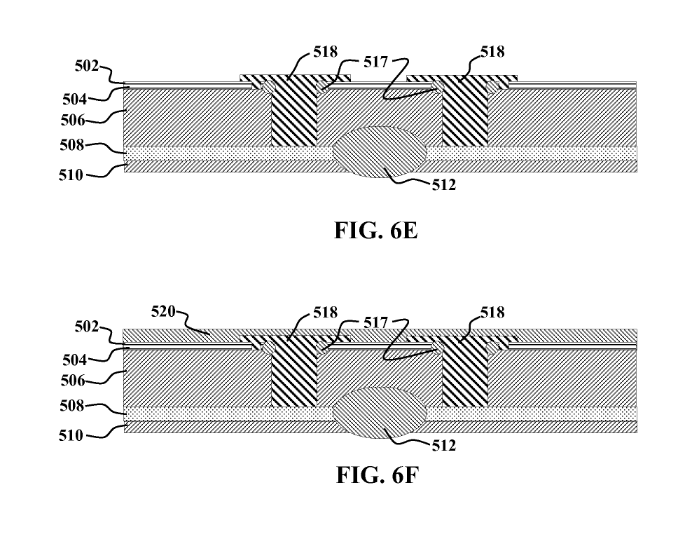

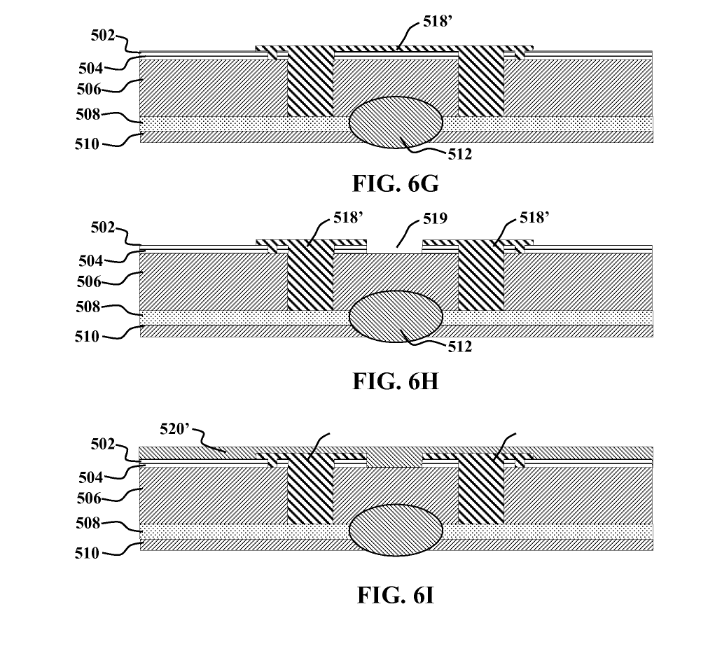

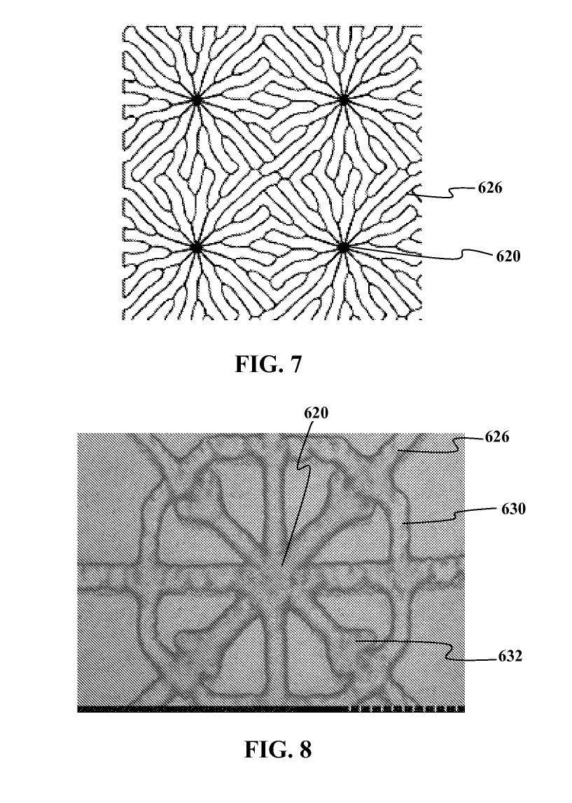

The device layers 102, 112 are preferably of a type that can be manufactured on a large scale, e.g., in a roll-to-roll processing system. There are a large number of different types of device architectures that may be used in the device layers 102, 112. By way of example, and without loss of generality, the inset in FIG. 1A shows the structure of a CIGS active layer 107 and associated layers in the device layer 102. By way of example, the active layer 107 may include an absorber layer 130 based on materials containing elements of groups IB, IIIA and VIA. Preferably, the absorber layer 130 includes copper (Cu) as the group IB, Gallium (Ga) and/or Indium (In) and/or Aluminum as group IIIA elements and Selenium (Se) and/or Sulfur (S) as group VIA elements. Examples of such materials (sometimes referred to as CIGS materials) are described in U.S. Pat. No. 6,268,014, issued to Eberspacher et al on Jul. 31, 2001, and US Patent Application Publication No. US 2004-0219730 A1 to Bulent Basol, published Nov. 4, 2004, both of which are incorporated herein by reference. A window layer 132 is typically used as a junction partner between the absorber layer 130 and the transparent conducting layer 109. By way of example, the window layer 132 may include cadmium sulfide (CdS), zinc sulfide (ZnS), or zinc selenide (ZnSe) or some combination of two or more of these. Layers of these materials may be deposited, e.g., by chemical bath deposition or chemical surface deposition, to a thickness of about 50 nm to about 100 nm. A layer 134 of a metal different from the bottom electrode may be disposed between the bottom electrode 104 and the absorber layer 130 to inhibit diffusion of metal from the bottom electrode 104. For example, if the bottom electrode 104 is made of aluminum, the layer 134 may be a layer of molybdenum. This may help carry electrical charge and provide certain protective qualities. In addition, another layer 135 of material similar to that of layer 13 may also be applied between the layer 134 and the aluminum layer 104. The material may be the same as that of layer 13 or it may be another material selected from the set of material listed for layer 13. Optionally, another layer 137 also be applied to the other side of layer 104. The material may be the same as that of layer 135 or it may be another material selected from the set of material listed for layer 13. Protective layers similar to layers 135 and/or 137 may be applied around the foil on any of the embodiments described herein, such as but not limited to those of FIGS. 5 and 6.

Although CIGS solar cells are described for the purposes of example, those of skill in the art will recognize that embodiments of the series interconnection technique can be applied to almost any type of solar cell architecture. Examples of such solar cells include, but are not limited to: cells based on amorphous silicon, Graetzel cell architecture (in which an optically transparent film comprised of titanium dioxide particles a few nanometers in size is coated with a monolayer of charge transfer dye to sensitize the film for light harvesting), a nanostructured layer having an inorganic porous semiconductor template with pores filled by an organic semiconductor material (see e.g., US Patent Application Publication US 2005-0121068 A1, which is incorporated herein by reference), a polymer/blend cell architecture, organic dyes, and/or C₆₀ molecules, and/or other small molecules, micro-crystalline silicon cell architecture, randomly placed nanorods and/or tetrapods of inorganic materials dispersed in an organic matrix, quantum dot-based cells, or combinations of the above. Furthermore, embodiments of the series interconnection technique described herein can be used with optoelectronic devices other than solar cells.

Alternatively, the optoelectronic devices 101, 111 may be light emitting devices, such as organic light emitting diodes (OLEDs). Examples of OLEDs include light-emitting polymer (LEP) based devices. In such a case, the active layer 107 may include a layer of poly (3,4) ethylendioxythiophene:polystyrene sulfonate (PEDOT:PSS), which may be deposited to a thickness of typically between 50 and 200 nm on the bottom electrodes 104, 114, e.g., by web coating or the like, and baked to remove water. PEDOT:PSS is available from Bayer Corporation of Leverkusen, Germany. A polyfluorene based LEP may then be deposited on the PEDOT:PSS layer (e.g., by web coating) to a thickness of about 60-70 nm. Suitable polyfluorene-based LEPs are available from Dow Chemicals Company.

The transparent conductive layer 109 may be, e.g., a transparent conductive oxide (TCO) such as zinc oxide (ZnO) or aluminum doped zinc oxide (ZnO:Al), which can be deposited using any of a variety of means including but not limited to sputtering, evaporation, CBD, electroplating, CVD, PVD, ALD, and the like. Alternatively, the transparent conductive layer 109 may include a transparent conductive polymeric layer, e.g. a transparent layer of doped PEDOT (Poly-3,4-Ethylenedioxythiophene), which can be deposited using spin, dip, or spray coating, and the like. PSS:PEDOT is a doped, conducting polymer based on a heterocyclic thiophene ring bridged by a diether. A water dispersion of PEDOT doped with poly(styrenesulfonate) (PSS) is available from H.C. Starck of Newton, Mass. under the trade name of Baytron® P. Baytron® is a registered trademark of Bayer Aktiengesellschaft (hereinafter Bayer) of Leverkusen, Germany. In addition to its conductive properties, PSS:PEDOT can be used as a planarizing layer, which can improve device performance. A potential disadvantage in the use of PEDOT is the acidic character of typical coatings, which may serve as a source through which the PEDOT may chemically attack, react with, or otherwise degrade the other materials in the solar cell. Removal of acidic components in PEDOT may be carried out by anion exchange procedures. Non-acidic PEDOT can be purchased commercially. Alternatively, similar materials can be purchased from TDA materials of Wheat Ridge, Colo., e.g. Oligotron™ and Aedotron™.

The gap between the first device module 101 and the second device module 111 may be filled with a curable polymer, e.g epoxy or silicone. An optional encapsulant layer (not shown) may cover the array 100 to provide environmental resistance, e.g., protection against exposure to water or air. The encapsulant may also absorb UV-light to protect the underlying layers. Examples of suitable encapsulant materials include one or more layers of fluoropolymers such as THV (e.g. Dyneon's THV220 fluorinated terpolymer, a fluorothermoplastic polymer of tetrafluoroethylene, hexafluoropropylene and vinylidene fluoride), Tefzel® (DuPont), Tefdel, ethylene vinyl acetate (EVA), thermoplastics, polyimides, polyamides, nanolaminate composites of plastics and glasses (e.g. barrier films such as those described in commonly-assigned, co-pending U.S. Patent Application Publication US 2005-0095422 A1, to Brian Sager and Martin Roscheisen, entitled “INORGANIC/ORGANIC HYBRID NANOLAMINATE BARRIER FILM” which is incorporated herein by reference), and combinations of the above.

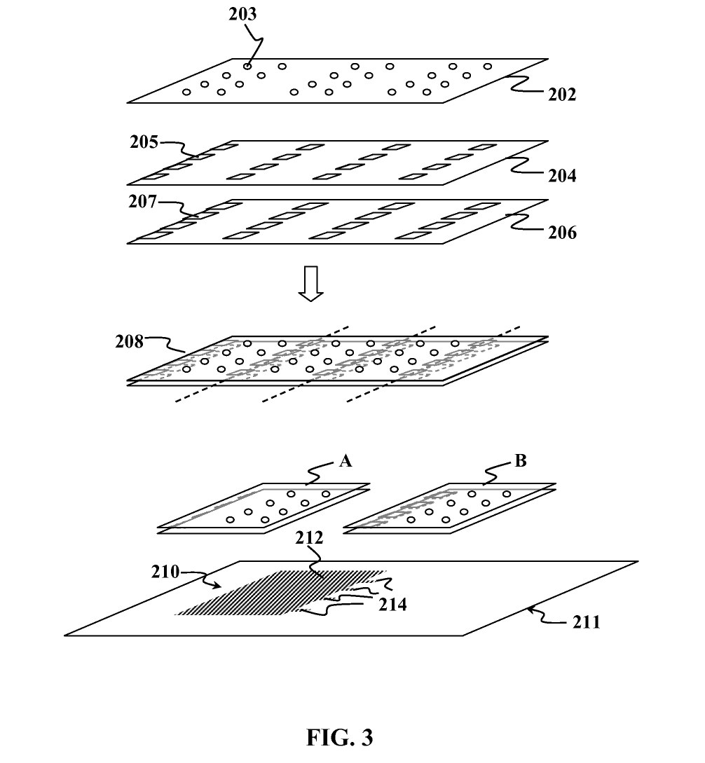

There are a number of different methods of fabricating interconnected devices according to embodiments of the present invention. For example, FIG. 3 illustrates one such method. In this method the devices are fabricated on a continuous device sheet 202 that includes an active layer between a bottom electrode and a transparent conductive layer, e.g., as described above with respect to FIGS. 2A-2B. The device sheet 202 is also patterned with contacts 203 like the contact 120 depicted in FIG. 2A. The contacts 203 may be electrically connected by conductive traces (not shown) as described above. An insulating layer 204 and a back plane 206 are also fabricated as continuous sheets. In the example shown in FIG. 3, the insulating layer 204 has been cut back, e.g., to form notches 205 that align with similar notches 207 in the back plane layer 206. The notches in the back plane layer 206 are larger than the notches in the insulating layer 204. The device sheet 202, insulating layer 204 and back plane layer are laminated together to form a laminate 208 having the insulating layer 204 between the device sheet 202 and the back plane 206. The laminate 208 is then cut into two or more device modules A,B along the dashed lines that intersect the notches 205, 207. A pattern of conductive adhesive 210 (e.g., a conductive polymer or silver ink) is then disposed on a carrier substrate 211. The modules are adhered to the carrier substrate 211. A larger area 212 of the conductive adhesive 210 makes electrical contact with the backplane 206 of module A. Fingers 214 of conductive adhesive 210 project out from the larger area 212. The fingers 214 align with the notches 205, 207 of module B. Extra conductive adhesive may be placed on the fingers 214 to facilitate electrical contact with the bottom electrode of module B through the notches 205, 207. Preferably, the fingers 214 are narrower than the notches 207 in the back plane 206 so that the conductive adhesive 210 does not make undesired electrical contact with the back plane 206 of module B.

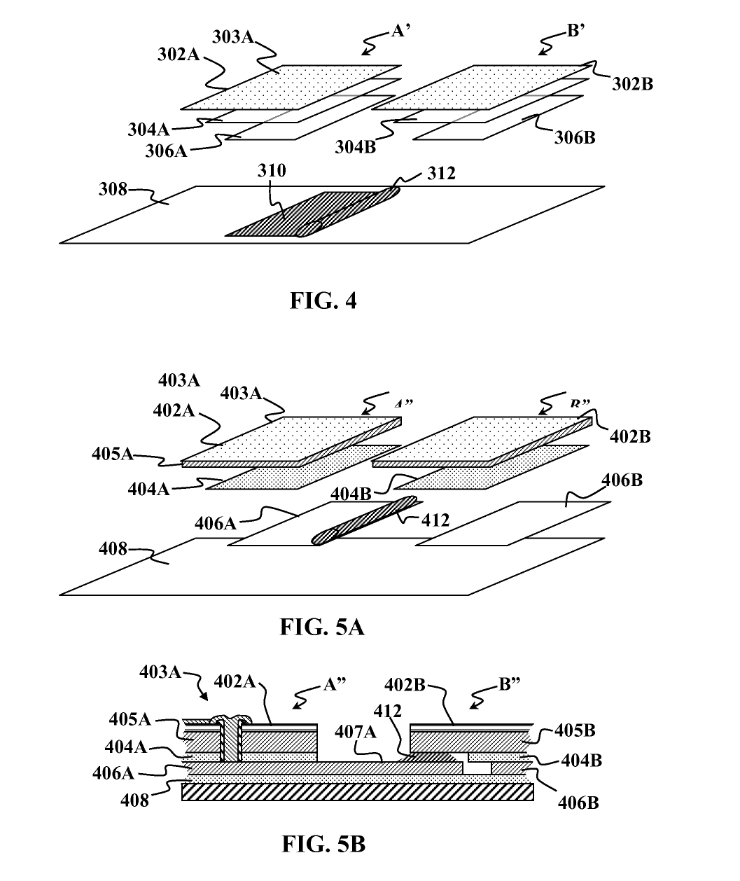

In the embodiment depicted in FIG. 3, the device sheet, insulating layer and back plane were laminated together before being cut into individual modules. In alternative embodiments, the layers may be cut first and then assembled into modules (e.g., by lamination). For example, as shown in FIG. 4, first and second device modules A′, B′ may be respectively laminated from pre-cut device layers 302A, 302B, insulating layers 304A, 304B, and back planes 306A, 306B. Each device layer 302A, 302B includes an active layer between a transparent conducting layer and a bottom electrode. At least one device layer 302A includes electrical contacts 303A (and optional conductive traces) of the type described above.

In this example, the back plane layer 306B of module B has been cut back by simply making it shorter than the insulating layer 304B so that the insulating layer 304B overhangs an edge of the back plane layer 306B. Similarly, the insulating layer 304B has been cut back by making it shorter than the device layer 302B or, more specifically, shorter than the bottom electrode of device layer 302B. After the pre-cut layers have been laminated together to form the modules A′, B′ the modules are attached to a carrier substrate 308 and electrical connection is made between the back plane 306A of module A′ and the bottom electrode of the device layer 302B of module B′. In the example shown in FIG. 4, the connection is made through a conductive adhesive 310 with a raised portion 312, which makes contact with the bottom electrode while avoiding undesired contact with the back plane 306B of module B′.

FIGS. 5A-5B depict a variation on the method depicted in FIG. 4 that reduces the use of conductive adhesive. First and second device modules A″, B″ are assembled from pre-cut device layers 402A, 402B, insulating layers 404A, 404B and back plane layers 406A, 406B and attached to a carrier substrate 408. Insulated electrical contacts 403A make electrical contact through the device layers 402A, a bottom electrode 405A and the insulating layer 406A as shown in FIG. 5B. Front edges of the insulating layer 404B and back plane 406B of module B″ are cut back with respect to the device layer 402B as described above with respect to FIG. 4. To facilitate electrical contact, however, a back edge of the back plane 406A of module A″ extends beyond the back edges of the device layer 402A and insulating layer 404A. As a result, the device layer 402B of module B″ overlaps the back plane 406A of module A″. A ridge of conductive adhesive 412 on an exposed portion 407A of the back plane 406A makes electrical contact with an exposed portion of a bottom electrode 405B of the device layer 402B as shown in FIG. 5B. Optionally, other electrical joining techniques such but not limited to soldering, welding, laser welding, ultrasonic welding or the like may be used to form electrical contact between back plane 406A and bottom electrode 405B.

In preferred embodiments of the methods described above, individual modules may be fabricated, e.g., as described above, and then sorted for yield. For example, two or more device modules may be tested for one or more performance characteristics such as optoelectronic efficiency, open circuit voltage, short circuit current, fill factor, etc. Device modules that meet or exceed acceptance criteria for the performance characteristics may be used in an array, while those that fail to meet acceptance criteria may be discarded. Examples of acceptance criteria include threshold values or acceptable ranges for optoelectronic efficiency or open circuit voltage. By sorting the device modules individually and forming them into arrays, higher yields may be obtained than by fabricating arrays of devices monolithically.

In the discussion of the electrical contacts 120 between the transparent conductive layer and the back plane, vias were formed, coated with an insulating material and filled with a conductive material. In an alternative embodiment, connection between the transparent conductive layer and the back plane may be effected using a portion of the bottom electrode as part of the electrical contact. FIGS. 6A-6H illustrate examples of how this may be implemented. Specifically, one may start with a structure 500 (as shown in FIG. 6A) with a transparent conducting layer 502 (e.g., Al:ZnO, i:ZnO), an active layer 504 (e.g., CIGS), a bottom electrode 506 (e.g., 100 um Al), an insulating layer 508 (e.g., 50 um PET), and a back plane 510 (e.g., 25 um Al). Preferably, the back plane 510 is in the form of a thin aluminum tape that is laminated to the bottom electrode 506 using an insulating adhesive as the insulating layer 508. This can greatly simplify manufacture and reduce materials costs.

Electrical connection 512 may be made between the bottom electrode 506 and the back plane at one or more locations as shown in FIG. 6B. For example, a spot weld may be formed through insulating layer 508, e.g., using laser welding. Such a process is attractive by virtue of making the electrical connection in a single step. Alternatively, the electrical connection 512 may be formed through a process of drilling a blind hole through the back plane 510 and the insulating layer 508 to the bottom electrode and filling the blind hole with an electrically conductive material such as a solder or conductive adhesive.

As shown in FIG. 6C, a trench 514 is then formed in a closed loop (e.g., a circle) around the electrical connection 512. The closed-loop trench 514 cuts through the transparent conducting layer 502, active layer 504, and bottom electrode 506, to the back plane 510. The trench 514 isolates a portion of the bottom electrode 506, active layer 504, and transparent conductive layer 502 from the rest of the structure 500. Techniques such as laser machining may be used to form the trench 514. If laser welding forms the electrical connection 512 with one laser beam and a second laser beam forms the trench 514, the two laser beams may be pre-aligned with respect to each other from opposite sides of the structure 500. With the two lasers pre-aligned, the electrical connection 512 and trench 514 may be formed in a single step, thereby enhancing the overall processing speed.

The process of forming the isolation trench may cause electrical short-circuits 511, 517 between the transparent conductive layer 502 and the bottom electrode 506. To electrically isolate undesirable short circuits 511 formed on an outside wall 513 of the trench 514 an isolation trench 516 is formed through the transparent conductive layer and the active layer to the bottom electrode 506 as shown in FIG. 6D. The isolation trench 516 surrounds the closed-loop trench 514 and electrically isolates the short circuits 511 on the outside wall 513 of the trench from the rest of the structure 500. A laser scribing process may form the isolation trench 516. A lesser thickness of material being scribed reduces the likelihood of undesired short circuits resulting from formation of the isolation trench 516.

Not all short circuits between the transparent conducting layer 502 and the bottom electrode 506 are undesirable. Electrical shorts 517 along an inside wall 515 of the trench 514 can provide part of a desired electrical path to the electrical connection 512. If a sufficient amount of desirable short circuiting is present, the electrical contact may be completed as depicted in FIG. 6E-6F. First an insulating material 518 is deposited into the closed-loop trench 514 and isolation trench 516 e.g., in a “donut” pattern with a hole in the middle as shown in FIG. 6E. Next electrically conductive fingers 520 are deposited over portions of the structure 500 including the isolated portion surrounded by the trench 514 and non-isolated portions as depicted in FIG. 6F. The insulating material 518 may be deposited in a way that provides a sufficiently planar surface suitable for forming the conductive fingers 520. Electrical contact is then made between the transparent conducting layer 502 in the non-isolated portions outside the trench 514 and the back plane 510 through the fingers 520, the transparent conducting layer within the isolated portion, electrical shorts 517 on the inside wall of the trench 514, the portion of the bottom electrode 506 inside the trench 514 and the electrical connection 512.

Alternatively, if the shorts 517 do not provide sufficient electrical contact, a process of drilling and filling may provide electrical contact between the fingers 520 and the isolated portion of the bottom electrode 506. In an alternative embodiment depicted in FIGS. 6G-6I, it is possible that insulating material 518′ covers the isolated portion when it is deposited as shown in FIG. 6G. The insulating material 518′ covering the isolated portion may be removed, e.g., by laser machining or mechanical processes such as drilling or punching, along with corresponding portions of the transparent conductive layer 502 and the active layer 504 to expose the bottom electrode 506 through an opening 519 as shown in FIG. 6H. Electrically conductive material 520′ forms conductive fingers, as described above. The electrically conductive material makes contact with the exposed bottom electrode 506 through the opening 519 and completes the desired electrical contact as shown in FIG. 6I.

Note that there are several variations on the techniques described above with respect to FIGS. 6A-6I. For example, in some embodiments it may be desirable to make the electrical connection 512 after the closed-loop trench has been formed and filled with insulating material. There are several advantages of the above-described process for forming the electrical contact. The process steps are simplified. It is easier to deposit the insulating layer without worrying about covering up the back plane. The process allows for a planar surface for depositing the fingers 520, 520′. Reliable electrical contact can be made between the bottom electrode 506 and the back plane 510 through laser welding. Furthermore, electrical shorts can be isolated without jeopardizing a 100% yield.

Referring now to FIG. 7, another aspect of the present invention will now be described. This embodiment of the present invention relates to the provision of low-cost structures and materials for photovoltaic cells which yield low shadowing and resistive losses from conductors facing the incoming sunlight, and which facilitate series interconnection.

Transparent conductor (TC) layers, particularly solution coated, traditionally have a level of resistivity that creates undesired electrical losses in a photovoltaic device. One known way to address this resistivity issue is to apply a thin conductive trace to the TC. The trace, which may be made of highly conductive metal having a resistivity, for example, in the vicinity of about 1-50×10−6 Ω·cm. In known devices using conventional traces, the area (shadowing) loss in such an optimized structure is about 11%, and the total is about loss 19% with a TC sheet resistance of 40 Ω/square. Unfortunately, even with printed traces, fingers, or grids, there is still loss of efficiency for two reasons. First, the fingers are opaque and so present a shadow to the photovoltaic material underneath. Second, the fingers have a finite resistance which leads to some power dissipation. These factors have an optimum, since minimizing shadowing implies narrower fingers, while minimizing resistance implies larger fingers. Furthermore, very small fingers tend to be impractical to fabricate because they require expensive techniques. Although the highest conductivity traces may be obtained from vacuum deposited metals, the method requires expensive deposition systems as well as patterning.

Referring now to FIGS. 1 and 7, although the structure of the present invention greatly reduces the conductivity requirement for the TC, it is advantageous to have even greater reductions, which may be achieved by the provision of fingers which are narrower (and hence less obstructive of light) than those conventionally used. By proper configuration of the size and shape of such fingers, traces, or grids, small losses on the order of about 10% or less can be achieved with a TC having sheet resistance of as large as about 200 Ω/sq., which is more than 10 times as large as required by conventional structures. In another embodiment, the total losses from finger shadowing and electrical resistance is about 5% or less. The ZnO or TC thickness may be reduced to ˜50-250 nm

Referring to FIG. 7, the traces 626 may interconnect multiple vias 620 of the EWT structure to reduce the overall sheet resistance. It should be understood that a variety of patterns or orientations for the traces 626 may be used as shown in FIG. 7 and as previously shown in FIGS. 2B-2D. By way of nonlimiting example, the vias 620 may be spaced about 1 centimeter apart from one another with the traces 626 connecting each contact with its nearest neighbor or in some cases to the transparent conductor surrounding it. The traces 626 may have a width between about 1 micron and about 200 microns, preferably between about 5 microns and about 50 microns. Wider lines imply a larger separation in order to avoid excessive shadowing loss.

Calculations show that for typical commercially available materials for traces such as but not limited to conductive epoxies with resistivities in the range of 1-10×10⁻⁵ Ω·cm, linewidth is a critical factor, and widths as small as about 25 microns are desirable, which leads to a shadowing loss of about 2.5% at 1 mm spacing. The vertical thickness of the lines may be about 1 to about 20 microns in height. In one embodiment of the present invention, the separation of lines is ideally in the vicinity of about 1 to about 2 mm, and the length about 0.5 mm. The sheet resistance of the traces may be below about 150 mΩ/square, and ideally not more than about 50 mΩ/square. Various combinations of width, spacing, length, thickness and resistivity of the traces around these values can be used to achieve comparably small total losses. As a nonlimiting example, in other embodiments with larger linewidths, the cross-sectional area of the fingers, traces, or grids are such that they achieve a total loss of about 10% or less. The overall cross-sectional area may reduce the electrical loss in a manner sufficient to compensate for loss related to increased shadowing from any increase in linewidth. In one embodiment, the cross-sectional area of the traces are sized so that the sheet resistances of the fingers is between about 150 mΩ/square and about 50 mΩ/square. In substantially all cases, the advantage of printing such traces is the large reduction in thickness and/or conductivity required from the transparent conductor, which thereby provides major reductions in both materials and fabrication equipment costs and optical % transmission losses from the transparent conductor.

In another embodiment of the present invention, to obtain 25 micron linewidths on properly prepared substrates, a variety of techniques such as but not limited to gravure printing may be used to provide the desired linewidth. Screen printing may also be used to provide line heights from about 5- about 25 microns or more, giving rise to a third dimension of variability in line width while maintaining conductivity. In one embodiment, the line height may be in the range of non-screen printed traces may be about 1 to about 10 microns. In another embodiment, the line height may be in the range of non-screen printed traces may be about 2 to about 6 microns. In yet another embodiment, the line height may be in the range of about 3 to about 5 microns. Because screen printing typically uses higher viscosity materials, it is capable of thicker deposits than other techniques, and when properly applied can provide narrow lines of width less than 50 microns.

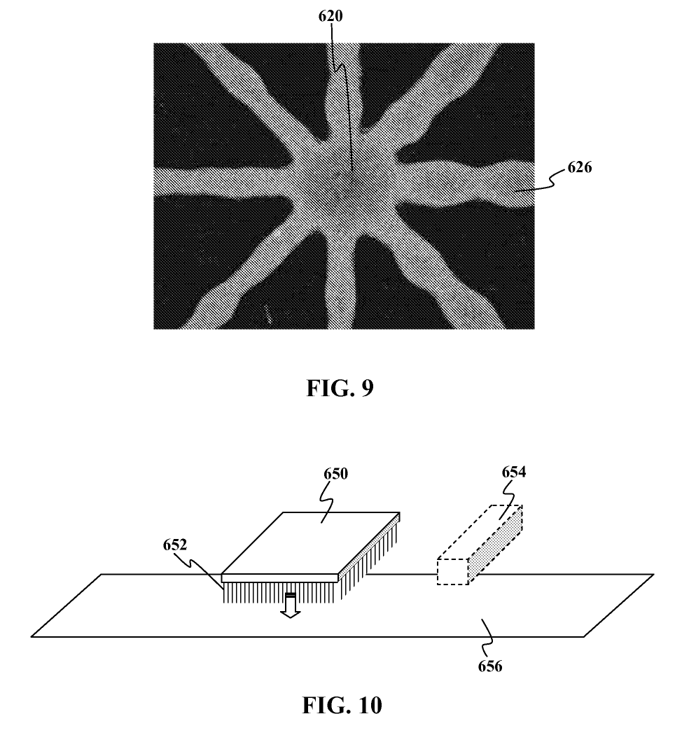

FIGS. 8 and 9 show other possible trace configurations. For example, FIG. 8 shows multiple intersecting traces 626 converging at a via 620. A hexagonal shaped trace 630 may also be used to intersect multiple traces 626 extending away from via 620. The linewidths may be in the ranges discussed above to achieve the desired. In one nonlimiting example, the lines may be sized to be a nominal width of about 60 μm wide lines, but may be as wide as about 150- about 200 μm. Sheet resistance may be about 1 Ω/sq. The pattern may also include bumps 632 which have wider linewidths for certain sections of the traces 626. Optionally, some trace patterns may be without the bumps 632. FIG. 9 shows a pattern where a plurality of traces 626 radiate away from a via 620. It should be understood that embodiments of the invention using these patterns may have linewidths in the range of about 5 to about 50 microns. In another embodiment, linewidths may be between about 70 and about 110 microns; sheet resistance of about 50 mΩ/sq. Some embodiments may have linewidths between about 20 to about 30 microns to provide total losses of about 10% or less.

Referring now to FIG. 10, yet another embodiment of the present invention will now be described. It should be understood that to make the EWT solar cell configuration economically viable, a method of fabricating large numbers of small vias rapidly in the substrate is desired. A practical manufacturing line desires throughput on the order of several square meters per minute. It would be highly impractical to do this in silicon wafers. In embodiments of the present invention, vias may be advantageously formed at these speeds in metal foils of a few thousandths of an inch thickness by mechanical punching units which punch many vias simultaneously, or by laser ablation. FIG. 10 shows one embodiment of a punching device 650 for use with the present invention. It includes a punch device 650 that may include a plurality of penetrating members 652 to create a plurality of via holes simultaneously. In other embodiments, a laser device 654 (shown in phantom) may optionally be used to ablate a plurality of via holes in the substrate 656. Still further embodiments may include, but are not limited to, punch, laser, or other hole forming devices that create each via hole individually instead of in a simultaneous, batch process.

The top conductor of thin film solar cells is often composed of a doped form of ZnO, which is a relatively brittle material that when sheared by a punch breaks cleanly rather than deforming. If this or any other TC used deforms so that there is a significant probability of the formation of electrical contacts between the TC and the bottom conductor (which is only 1-2 microns vertical distance away), it is desirable to remove the TC before punching. This may be accomplished in the case of ZnO by a short exposure to mild acid, for example acetic acid (although other acids may also be used). The acid is printed by a droplet dispenser into holes in a polymer screen which is temporarily laminated to the top of the device foil and held by tension until the acid is removed by rinsing. This removal process is especially useful if the vias are formed by laser ablation, since laser heating tends to melt the ZnO and all surrounding materials at the same time, and can possibly cause shorts.

Although not limited to the following, while there exists a range of values of several of the parameters available for choice, it is desirable that the diameter of the vias should not exceed 1 mm, and should be preferably smaller. For example, if the diameter of the vias is 1 mm and the via spacing 10 mm, the fractional loss due to via area is 0.8%; at 0.5 mm diameter it is 0.2%. However, at 1.5 mm diameter the loss is 1.8%.

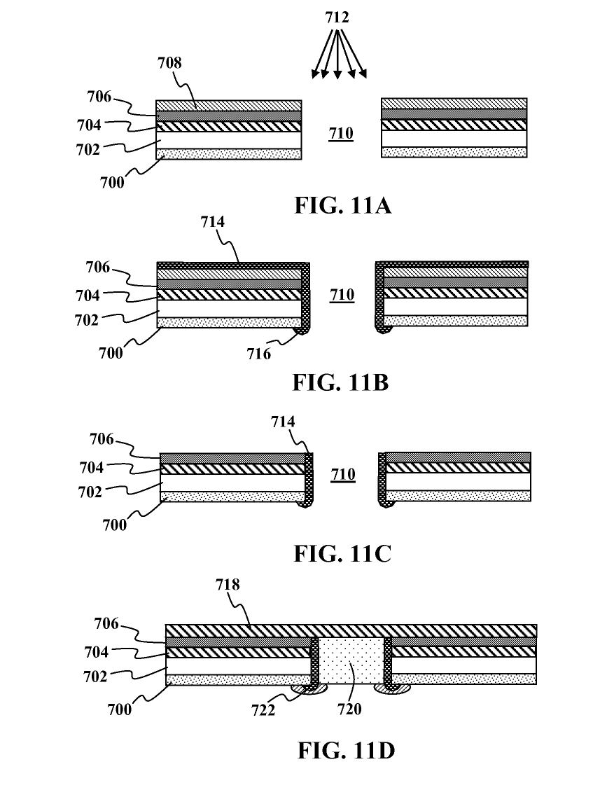

Referring now to FIGS. 11A-11D, yet another aspect of the present invention will now be described. FIG. 11A is a cross-sectional view showing a transparent conductor 700, a photovoltaic layer 702, a bottom electrode 704, insulating layer 706, and a liner 708. For ease of illustration, the photovoltaic layer 702 is shown as a single layer but should be understood that it may be comprised of multiple layers such as but not limited to the device shown in FIG. 2A. This device of FIG. 11A is an intermediate device with a via hole 710 that is not insulated. FIGS. 11A-11D show one method according to the present invention of insulating the via hole 710. As seen in FIG. 11A, the arrows 712 show the direction from which the insulating material will be sprayed. This spray may be applied using a variety of techniques including but not limited to an aerosol technique. The arrows 712 show that the spray is actually coming from an “underside” of the intermediate solar cell device. In this particle embodiment, the entire device has been flipped upside down to facilitate the spray process (i.e. the transparent conductor 700 is on the bottom of the stack). It should be understood that in other embodiments, the spray may come from the other direction or from both sides, sequentially or in combination. The spray of insulating material may also be applied without flipping the entire stack upside down in the manner shown in FIG. 11A. The insulating material may be EVA, PVOH, PVA, PVP, and/or another insulating material such as any thermoplastic polymer which has good adhesion to the metal foils 704 and 718. The EVA is preferably supplied as an emulsion of about 40-65% by weight in water. After application it is dried for about 90 seconds at 60-90 deg. with a Tg <150° C.

Referring now to FIG. 11B, the spray of insulating material as indicated by arrows 712 creates an insulating layer 714 that covers at least the side walls of the via hole 710. The insulating layer 714 may optionally be oversprayed to cover some portion of the transparent conductor 700 to ensure that the insulating layer fully insulates the sidewalls of the via hole 710. The overspray portion 716 may also improve adhesion of the insulating layer 714 to the stack of layers

FIG. 11C shows the liner 708 may be removed to remove the bottom layer of the insulating material 714. Optionally, it should be understood that the layer 708 may actually comprise of a plurality of discrete layers such as but not limited to a liner layer, an adhesive layer, and a liner layer. This may create a liner with better release qualities and/or adhesive qualities for the materials that they are in contact with. One liner material may interact better with one material than the other. This allows the liner to be optimized for the desired qualities. Still further, the layer 708 may have a plurality of discrete layers comprising of a liner layer, an adhesive layer, a PET or electrically insulating layer, an adhesive layer, and a liner layer configuration which guarantees election insulation by having the PET or electrically insulating layer.

FIG. 11D shows that with liner 708 removed, the backside electrode 718 may be applied to the underside of the stack. The stack is now cured in order to cause good adhesion of the backside electrode to the insulating layer. In the case of EVA, the cure takes place at about 150 C for about 20 min. It should be understood that in some embodiments of the present invention, the backside electrode 718 may be a foil of material that covers the entire backside. The via hole 710 is filled with a conductive material 720 and fingers 722 are coupled to the conductive material 720.

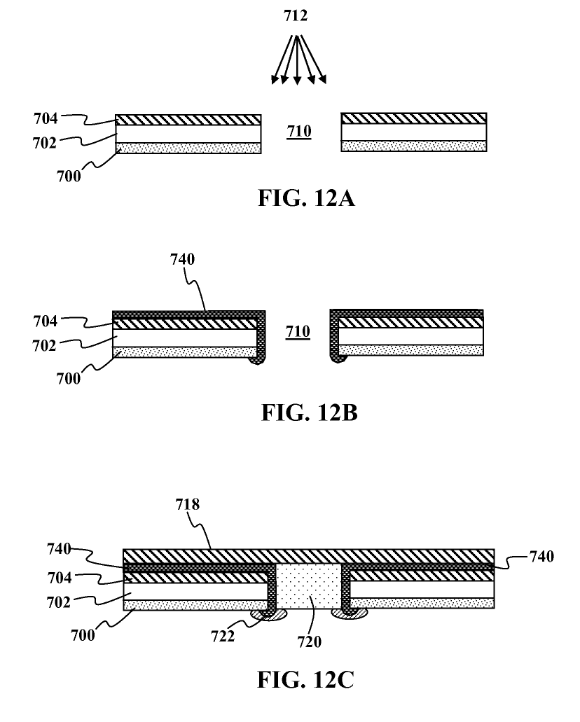

Referring now to FIGS. 12A-12C, yet another embodiment of the present invention will now be described. As seen in FIG. 12A, the stack of layers to be sprayed with insulating material does not include the liner 708 found previously in FIG. 11A. In the present embodiment, the insulating material also includes an adhesive quality. Hence, the insulating layer 740 when formed will not need to be removed from the underside and liner 708 is not needed, nor is insulating layer 706. Arrows 712 show that the insulating material may be sprayed on using one or more techniques such as but not limited to an aerosol technique to cover the sidewalls of the via hole 710 and the underside of the layer 706.

FIG. 12B shows that the insulating layer 740 forms a layer covering the sidewall of the via hole 710 and along substantially the entire backside of layer 706. This simplifies the number of steps as there is no need to have a liner removal step or prior application of an insulating layer. The backside electrode layer 718 (FIG. 12C) may be applied directly to the layer 740.

FIG. 12C shows that once the backside electrode layer 718 may be applied and a conductive material 720 added to form an electrical connection via the traces 722 to couple the transparent conductor layer 700 to the backside electrode 718 while being insulated from bottom electrode 704 by the insulating layer 740.

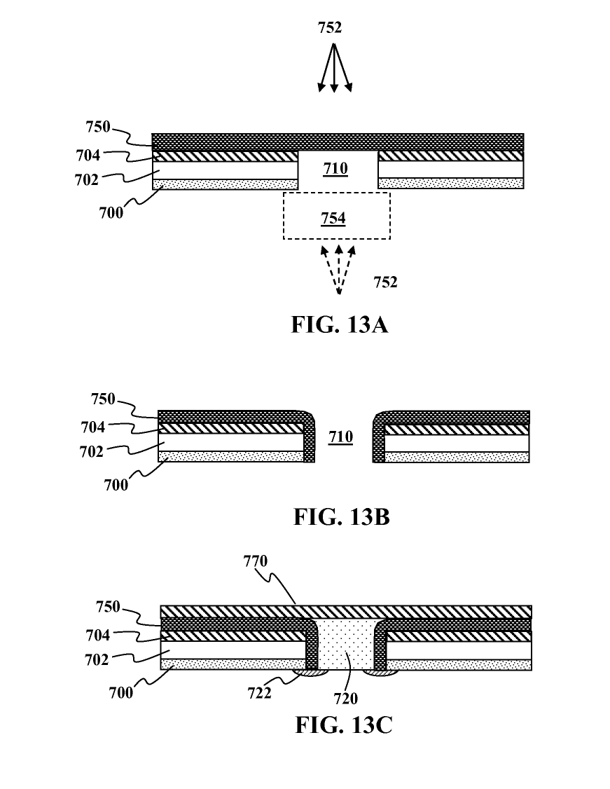

Referring now to FIGS. 13A-13B, a still further embodiment of the present invention will now be described. This embodiment of the invention describes another method of forming the insulating layer along the sidewalls of a via hole. As seen in FIG. 13A, a substantially uniform layer 750 of insulating material is formed along a backside of layer 704. Optionally, this layer 750 includes adhesive qualities to facilitate the attachment of the backside electrode layer 770. The layer 750 flows into the via and covers the side walls in a thickness comparable to its thickness on the bottom electrode 704. The exact thickness of the coating on the sidewall will depend to some extent on the aspect ratio of the via (the ratio of via diameter to foil thickness) as well as on the viscosity of the coating solution. In one embodiment, there is sufficient material to provide a layer between about 20 to about 100 microns thick along the wall of the via hole 710. It should be understood that some material from layer 750 may also fill part or all of the via hole 710. For ease of illustration, the layer 750 is depicted as extending over the via hole. A gas source as indicated by arrows 752 may be used to direct or flow the material from layer 750 into the via hole 710. Optionally, the source may blow gas, inert gas, or air. Still further, it should be understood that instead of blowing gas, a vacuum source 754 (shown in phantom) may be used instead or in combination with the gas source.

The layer 750 may be formed of sufficient thickness so that there is sufficient material to flow into the via and cover the side walls without being too thin and without filling the entire via hole. In one embodiment, the device may have a layer thickness in the range of about 50-100 microns. In another embodiment, the device may have a layer thickness in the range of about 50-100 microns. In another aspect, there is sufficient material in the layer 750 to coat the sidewalls of the via holes with insulating material about 20 to about 100 microns thick.

As seen in FIG. 13B, the via hole 710 remains open while the insulating layer 750 is formed by drawing the material towards the sidewalls in the via hole 710. The via hole 710 remains open to allow a conductive material 720 to be filled into the via hole 710. This method of printing a uniform layer may allow for a thicker layer of the insulating layer 750 to be formed along the walls of the via.

FIG. 13C shows that the backside electrode layer 770 may be coupled to the layer 750. The via hole 710 is filed with a conductive material 720 and is coupled to fingers 722 which electrically couple the transparent conductor 700 to the backside electrode 770.

It should be understood of course that the methods using spraying and the methods using air impingement (by way of positive and/or negative pressure) are combinable in single or multiple steps. As a nonlimiting example, the spray-on application of insulating material may be subsequently treated by air impingement (via positive and/or negative pressure) to ensure that any material that may occlude a via hole from the spray on application are directed to coat the sidewalls of the via or to ensure that the sidewalls are fully coated. Optionally, in another nonlimiting example, insulating material applied using the uniform coating and air impingement technique may be supplemented with spraying insulating material onto at least the sidewalls of the via hole if the layer is not of a desired thickness. In yet another nonlimiting example, an initial layer of insulating material may be sprayed onto the sidewall of the via holes and then a uniform coating may be applied to using the air impingement technique to further thicken the insulating layer. In still other embodiments, two spray-on steps may be used to build up layer thickness. Another embodiment may use two coating steps (with air impingement after each coat) to build up the desired thickness.

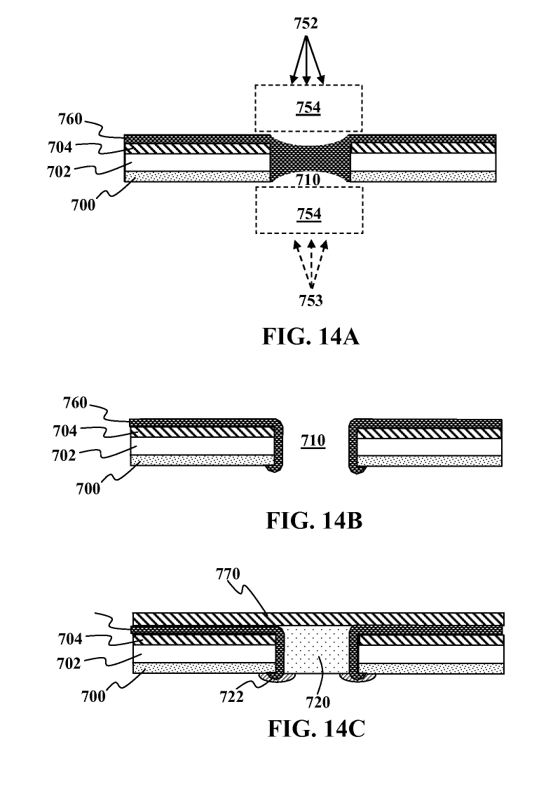

Referring now to FIGS. 14A-14B, yet another embodiment of the present invention will now be described. FIG. 14A shows that a layer of insulating material 760 is applied over the layer 704. In this embodiment, the layer of material 760 is applied in a manner such that substantially all of the vias are plugged or at least partially filled with the material of layer 760. In other embodiments, only a portion of the vias are plugged. By way of nonlimiting example, the material of layer 760 may be EVA, PVOH, PVA, PVP, UV curable insulating ink, a thermoplastic polymer with a Tg less than about 150° C., or combinations thereof. The thickness of the material may be substantially the same range as recited for FIGS. 12-13. A variety of solution-based coating techniques may be used to deposit the material 760 including but is not limited to wet coating, spray coating, spin coating, doctor blade coating, contact printing, top feed reverse printing, bottom feed reverse printing, nozzle feed reverse printing, gravure printing, microgravure printing, reverse microgravure printing, comma direct printing, roller coating, slot die coating, meyerbar coating, lip direct coating, dual lip direct coating, capillary coating, ink jet printing, jet deposition, spray deposition, and the like, as well as combinations of the above and/or related technologies.

Optionally, sprayers which can be used to deposit films include, for example, ultrasonic nozzle sprayers, air atomizing nozzle sprayers and atomizing nozzle sprayers. In ultrasonic sprayers, disc-shaped ceramic piezoelectric transducers covert electrical energy into mechanical energy. The transducers receive electrical input in the form of a high-frequency signal from a power supply that acts as a combination oscillator/amplifier. In air atomizing sprayers, the nozzles intermix air and liquid streams to produce a completely atomized spray. In atomizing sprayers, the nozzles use the energy of from a pressurized liquid to atomize the liquid and, in turn, produce a spray.

As seen in FIG. 14A, the via hole 710 may be at least partially plugged by the material 760. In this present embodiment, the partial plugging of the via provides excess material in the via 710 to ensure that sufficient material 760 is present to cover the side walls of the via 710. Gas and/or vapor may be forced through the via 710 to “clear” the plugged via but still leave some material 760 on the side wall of the via 710. A source 752 may blow gas, inert gas, or air to create an opening through the occluded via. In some embodiments of this invention, an air knife, continuous air jet, jet air, pulsed air, non-pulsed air, and/or other air impingement technique may be used to un-occlude the via 710. In any of the foregoing, gas of other types such as but not limited to inert gas may be substituted in place of air. Optionally, the source 752 may be located above the target surface or below the target surface. Optionally, two or more sources may be used. As a nonlimiting example, sources 752 and 753 may be provided both above and below the target surface, operating sequentially, operating simultaneously, or otherwise in other timing patterns. The sources 752 and 753 may use the same type of gas or different types. Optionally, the orientation of the sources 752 and/or 753 may be varied. In embodiments using only one source, the source may be oriented to blow orthogonal to the target or at an angle. Again the single source may be above or below the target surface. Some embodiments with more than one source may have sources blowing orthogonal to the target, others may blow at an angle, while some may use both an orthogonally oriented source and a non-orthogonal source.

FIG. 14B shows that with the via 710 unplugged, the material 760 will extend into the via 710 and cover at least a portion of the sidewall therein. Optionally, the material 760 will cover substantially all of the sidewall in the via 710. As seen, the clearing of the via 710 will leave material 760 both above and below the via. As seen, the clearing of the via 710 may create a portion 762 of material 760 that covers around the via 710. This provides additional material to protect against undesirable electrical shorting.

FIG. 14C shows additional material layers added to complete this embodiment of the invention. The via hole 710 is filled with a conductive material 720 and electrically conductive fingers 722 are coupled to the conductive material 720. The backside electrode layer 770 may be coupled to the layer 760. The conductive material 720 and is coupled to fingers 722 which electrically couple the transparent conductor 700 to the backside electrode 770. It should be understood that the backside electrode 770 may be comprised of one or more of the following: stainless steel, copper, titanium, molybdenum, steel, aluminum, copper-plated or coated versions of any of the foregoing, silver plated or coated versions of any of the aforementioned, gold-plated or coated versions of the foregoing, or combinations thereof.

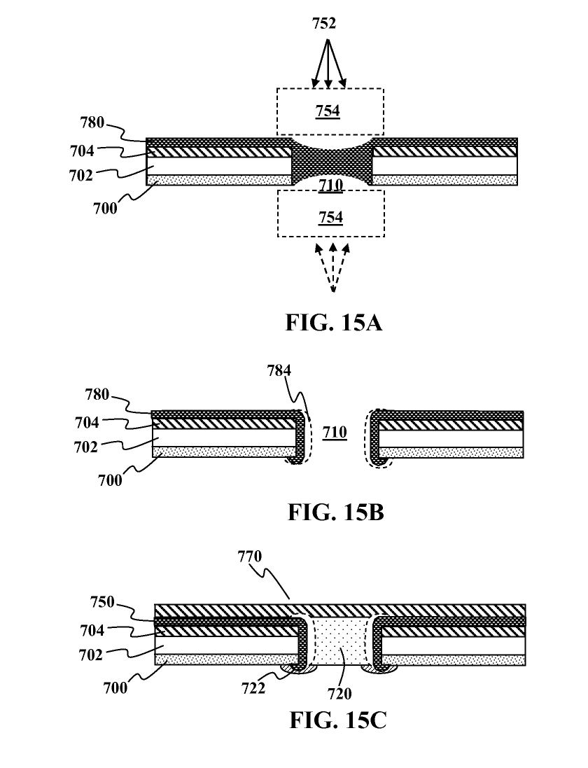

Referring now to FIGS. 15A-15C, yet another of the invention will now be described. This embodiment shows that an insulating layer 780 may be applied to the electrode layer 704. FIG. 15A shows the various methods of applying insulating layer 780, similar to that as shown for FIG. 14A. FIG. 15B shows that an additional layer 784 of insulating material (shown in phantom) may optionally be applied to the insulating layer 780. In one embodiment, the additional layer 784 may be comprised of the same material as that for the layer 780. Alternatively, in other embodiments, the layer 784 may be comprised of a different material. Optionally, the layer 784 may be comprised of ethyl vinyl acetate (EVA), poly vinyl alcohol (PVOH), polyvinyl acetate (PVA), poly vinyl pyrrolidone (PVP), UV curable insulating ink, and/or a thermoplastic polymer with a Tg less than about 150° C. FIG. 15C shows the other layers that may be applied. In one embodiment, the UV ink may be a UV curable urethane elastomer such as but not limited to Master Bond UV15X-5 from Master Bond Inc. The via hole 710 is filled with a conductive material 720 and electrically conductive fingers 722 are coupled to the conductive material 720. The backside electrode layer 770 may be coupled to the layer 780.

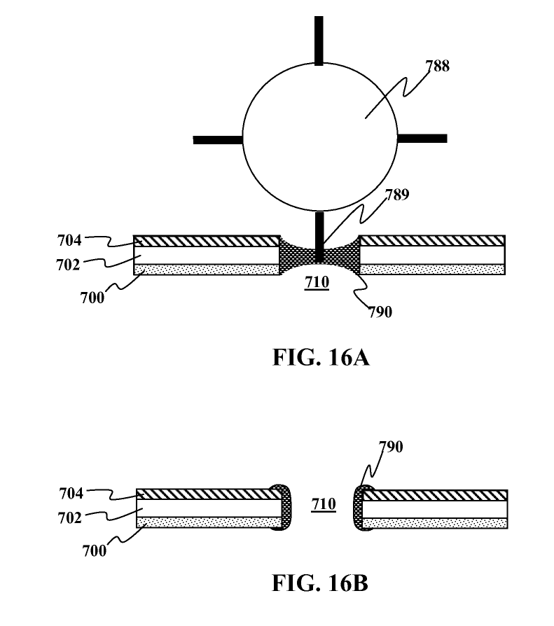

Referring now to FIGS. 16A-16B, still further alternative embodiments may be described. FIG. 16A shows a mechanical method for opening plugged vias. This may involve the lowering or passing of mechanical probes, needles, lancets, rods, or other projections through the occluded via 710. FIG. 16A shows a rotary device 788 with a plurality of probes 789 for piercing through the occlusions. This type of mechanical technique may be applied to open any of the occluded vias shown herein, including those described in FIGS. 13-15. FIG. 16A also shows that the insulating material 790 may be applied in a manner so as to fill the via 710 without substantially covering the surrounding surface. This may allow for more precise material utilization. By way of nonlimiting example, the material 790 deposited into the via 710 may be by ink jet techniques, needle deposition, squeegee, doctor blading, dropper technology, or combinations thereof.

FIG. 16B shows that in this embodiment, clearing the occlusion will leave a layer of material 790 along the side wall of the via 710. In some embodiments, this may provide sufficient electrical insulation. Optionally, in other embodiments, additional insulating material may be applied. By way of nonlimiting example, the additional insulating material may be solution deposited over the material 790 in method such as that shown in FIG. 13, 14, or 15. This will cover over the material 790 to ensure sufficient voltage resistance between the various electrically conductive layers. This second material may be the same as that used for material 790. Alternatively, they may be different materials, preferably both electrically insulating. Alternatively, one of the following may be applied first: ethyl vinyl acetate (EVA), poly vinyl alcohol (PVOH), polyvinyl acetate (PVA), poly vinyl pyrrolidone (PVP), UV curable insulating ink, and/or a thermoplastic polymer with a Tg less than about 150° C. After that, a different material from the aforementioned list (or other electrical insulator) may be applied over the layer 790.

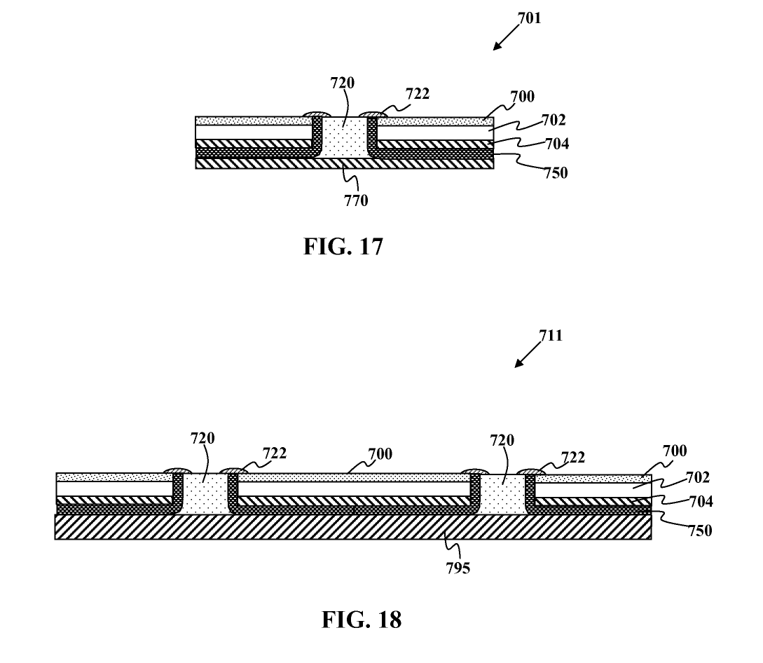

Referring now to FIGS. 17 and 18, another aspect of the present invention will now be described. FIG. 17 shows a cross-sectional view of one embodiment of a cell 701 with a via 720 in the cross-sectional area. The thickness of the backside conductor 770 is based on the maximum current that will be generated from the cell 701.

Referring now to FIG. 18, a larger cell 711 is shown with twice the active area and the number of vias 720 as the cell 701. This increase in cell size does not substantially increase the average density of fingers 722, vias 720, or any other top side opaque conductors on a top side or sunlight receiving area of the cell 711. This is enabled by the design of the cells 701 and 711. By way of nonlimiting example, if approximately 15% of the top side area of the cell 711 is occupied by an opaque electrical conductor, the density of those opaque conductors does not substantially change as the cell is increased in size to increase current. In most conventional cells which do not have vias 720 and which require top side busbars on the top side of the cell to collect the increased current from a larger cell, the increase in cell size also increases the density of busbars used per unit area of the cell to carry the higher current on the top side surface of the cell. The increase in busbars in conventional cells increases the percentage of top side area covered by opaque conductors, which decreases overall cell efficiency. Percentage-wise, a greater percentage of total cell area is covered or shaded by the busbars.

In the present embodiment, however, the increased current is carried on the underside of the cell 701 or 711. Thus increased ampacity to carry increase current does not require a percentage-wise loss of active area on the top side of the cell. Additionally, the backside conductor 795 in FIG. 18 is shown to be substantially thicker than the backside conductor 770 shown in FIG. 17. The percentage of coverage on the top side of the cell does not substantially change as cell size increases. As seen in FIG. 18, the increased ampacity is created by having more vias at substantially the same size and spacing as would be used in the smaller cell. In this manner, the distance a charge travels in the top side transparent conductor before it is collected by a conductive finger 722 or a via 720 is roughly the same in all sizes of the cell in the present embodiment of the invention. This keeps the pattern of fingers and vias consistent over the top side of the cell. The overall amount of current being collected by these fingers and vias, however, result in an aggregate increase in current. This aggregate increase is carried along the backside conductor 795 of the cell 711.

In the present embodiment, the top side conductors do not carry the charge directly out of the cells. They are merely charge collectors for the backside foil which then carries the collective charge of the cell to the next cell or to an exit connector. In one embodiment of the present invention, all or substantially all opaque conductors on the top or sunlight exposed side of the cell 711 are electrically coupled to the backside conductor 795. In another embodiment of the present invention, over 95% of all opaque conductors on the sunlight exposed side of the cell are electrically coupled to the backside conductor. In another embodiment of the present invention, over 90% of all opaque conductors on the sunlight exposed side of the cell are electrically coupled to the backside conductor. In another embodiment of the present invention, over 80% of all opaque conductors on the sunlight exposed side of the cell are electrically coupled to the backside conductor. Optionally, a ratio of opaque conductor area to exposed active area photovoltaic material is between about 1:9 to about 1:39. In one embodiment, the backside conductor may be a metal foil with a thickness between about 50 to about 100 microns. Optionally, the thickness of the backside conductor may be a metal foil with a thickness of between about 100 to 800 microns. In one embodiment, the metal foil may be comprised of aluminum, copper, stainless steel, molybdenum, or other combinations thereof. In one embodiment, the thin-film photovoltaic cells each sized to have a top side total area of about 10000 mm² or more to generate a current of greater than about 2 amperes. In another embodiment, the thin-film photovoltaic cells each sized to have a top side total area of about 21000 mm² to about 24000 mm² to generate a current of greater than about 5 amperes. In another embodiment, the thin-film photovoltaic cells each sized to have a top side total area of about 21000 mm² or more to generate a current of greater than about 5 amperes.

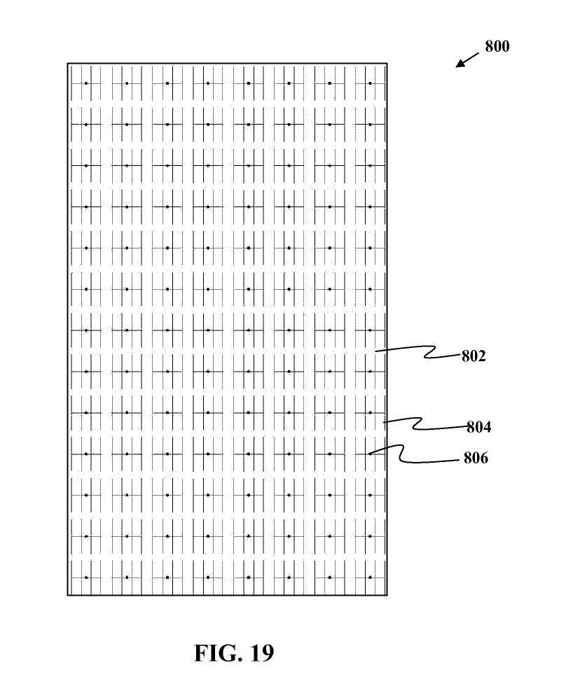

Referring now to FIG. 19, another embodiment of the present invention will now be described. FIG. 19 shows a top down view of a cell 800 with a total cell area comprised of a) active area 802 and b) areas shaded by fingers 804 and vias 806. This embodiment shows that about 8% of the total cell area is occupied by the opaque conductors formed by fingers 804 and vias 806. As seen in FIG. 19, the fingers 804 are formed from in straight lines and right angles from the center of the vias 806. Optionally, the one or more thin-film cells are sized to an area sufficiently large to generate a current greater than about 2 amperes under AM1.5G illumination and wherein less than about 15% of a top side surface area of the one or more cells comprises of an opaque conductor, irrespective of cell size. Optionally, less than about 10% of a top side surface area of the one or more cells comprises of the opaque conductor. Optionally, less than about 7.5% of a top side surface area of the one or more cells comprises of the opaque conductor. Optionally, less than about 5% of a top side surface area of the one or more cells comprises of the opaque conductor. Optionally, less than about 2.5% of a top side surface area of the one or more cells comprises of the opaque conductor. The decreased coverage of the top side by opaque conductors may be a result of thinner conductive lines used to form the fingers 804. In some embodiments, fingers 804 have widths of about 100 microns or less. In other embodiments, fingers 804 have widths of about 75 microns or less. In other embodiments, fingers 804 have widths of about 50 microns or less. In other embodiments, fingers 804 have widths of about 25 microns or less. Some embodiments may use decreased width but increased thickness to maintain the same amount of ampacity. Optionally, thinner fingers may result in patterns with more lines, which could be helpful in decreasing the distance charge travels in the transparent conductor before being collected by a finger 804 or via 806. Optionally, vias 806 with smaller diameters may also be used. Optionally, more vias 806 of smaller diameter may be used. The vias and/or fingers may be distributed in a regular pattern over the cell. Optionally, the vias and/or the fingers may be in an irregular pattern over the cell. Although most vias are shown as being formed vertically through the cell, some may be formed at an angle of 0 to 90 degrees relative to vertical.

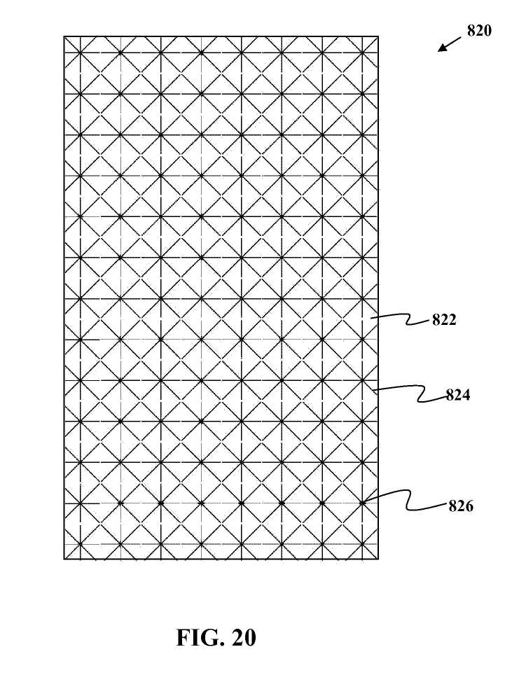

Referring now to FIG. 20, another embodiment of the present invention will now be described. FIG. 20 shows a top down view of a cell 820 with a total cell area comprised of a) active area 822 and b) areas shaded by fingers 824 and vias 826. This embodiment shows that about 7% of the total cell area is occupied by the opaque conductors formed by fingers 824 and vias 826. As seen in FIG. 20, the fingers 824 are formed in X-shaped patterns centered around the via 826. FIG. 20 shows two X's per via 826. Optionally, the pattern may be viewed as one X pattern and on + pattern per via 826. FIG. 20 also shows that the fingers 824 or conductive lines from the via are not coupled to fingers or lines coupled to another via. Optionally, some embodiments may use conductive lines from one via that are coupled to electrically conductive lines from one or more other vias. It may be advantageous in some embodiments to have the vias electrically isolated on the top side from other vias. This may help to isolate any shunts that may occur in the photovoltaic absorber layer and localize any cell defects. Optionally, in some embodiments, it may be useful to repair certain defects by electrically coupling certain vias to other vias along the top side of the cell. Some embodiments of the present invention may initially produce cells where fingers from different vias do not touch. Cells are then tested after manufacturing and areas of defects may be repaired by electrically connecting some fingers from select vias together to provide a bypass path to compensate for defects.

Embodiments herein may also be modified to include one or more of the following. In one embodiment, a ratio of opaque conductor area to exposed active area photovoltaic material is between about 1:9 to about 1:39. Optionally, increased cell size does not substantially increase cell shading due to increased ampacity of a backside electrical conductor to handle at least 5 amperes of current. Furthermore, increasing size of the cell does not increase the shading per unit area created by conductive fingers or traces over that unit area. As seen in FIG. 20, the increase in size does not change the front side pattern of conductive traces. The additional current is collected on the backside electrical conductor and does not increase shading per unit area. Optionally, the module includes one or more thin-film cells, wherein each of the one or more solar cells includes a backside electrical conductor having an average thickness of about 50 to about 100 microns. Optionally, the module includes one or more thin-film cells, wherein each of the one or more solar cells includes a backside electrical conductor having an average thickness of about 100 to about 800 microns. Optionally, the solar module includes one or more thin-film photovoltaic cells each sized to have a top side total area of about 10000 mm2 or more to generate a current of greater than about 2 amperes when under AM1.5G illumination. Optionally, the solar module includes one or more thin-film photovoltaic cells each sized to have a top side area of about 21000 mm2 or more to generate a current of greater than about 5 amperes when under AM1.5G illumination. Optionally, the solar module includes one or more thin-film photovoltaic cells each sized to have a top side area of about 21000 mm2 to about 24000 mm2 to generate a current of greater than about 5 amperes when under AM1.5G illumination. Optionally, the module has a low voltage electrical output with a voltage less than about 40 volts. Optionally, the module has a low voltage electrical output with a voltage less than about 20 volts. Optionally, the module has a low voltage electrical output with a voltage less than about 10 volts. Optionally, the module has a low voltage electrical output with a voltage less than about 1 volt. Optionally, the module has electrical output with a power greater than about 200 watts. Optionally, the module has electrical output with a power greater than about 100 watts. Optionally, the module has electrical output with a power greater than about 50 watts.

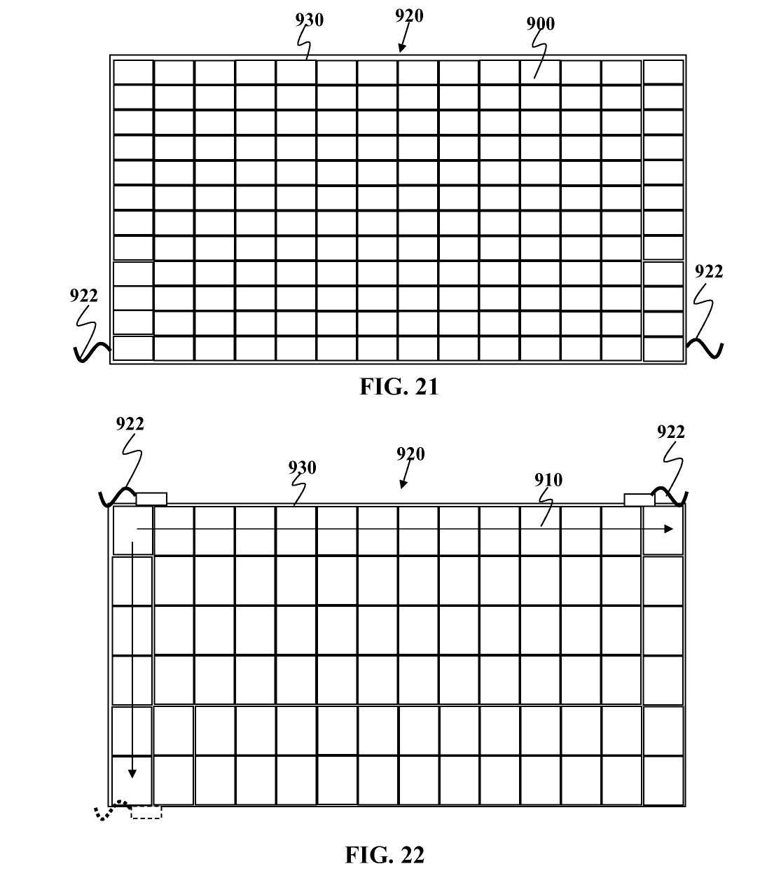

Referring now to FIG. 21, embodiments of the modules 20 used with the above assemblies will be described in further detail. FIG. 21 shows one embodiment of the module 920 with a plurality of solar cells 900 mounted therein. In one embodiment, the cells 900 are serially mounted inside the module packaging. In other embodiments, strings of cells may be connected in series connections with other cells in that string, while string-to-string connections may be in parallel. FIG. 21 shows an embodiment of module 920 with 168 solar cells 900 mounted therein. The solar cells 900 may be of various sizes. In this present embodiment, the cells 900 are about 135 mm by about 82 mm. As for the module itself, the outer dimensions may range from about 1900 mm to about 1970 by about 1000 mm to about 1070 mm. Optionally, the outer dimensions may range from about 1800 mm to about 2100 by about 900 mm to about 1200 mm. It should be understood that solar cells of other sizes and/or materials maybe used and these examples are purely exemplary and nonlimiting.

FIG. 22 shows yet another embodiment of module 920 wherein a plurality of solar cells 910 are mounted there. Again, the cells 910 may all be serially coupled inside the module packaging. Alternatively, strings of cells may be connected in series connections with other cells in that string, while string-to-string connections may be in parallel. FIG. 22 shows an embodiment of module 920 with 48 solar cells 910 mounted therein. The cells 910 in the module 920 are of larger dimensions. Having fewer cells of larger dimension may reduce the amount of space used in the module 920 that would otherwise be allocated for spacing between solar cells. The cells 910 in the present embodiment have dimensions of about 135 mm by about 164 mm. Again for the module itself, the outer dimensions may range from about 1900 mm to about 1970 by about 1000 mm to about 1070 mm. The electrical leads 922 from the modules may be mounted on the same side of the module. They may optionally be used with edge connectors as described in U.S. Provisional Application 60/862,979 fully incorporated herein by reference. Optionally, the connectors for leads 922 may be on different, opposing sides of the module. Optionally, the connectors for leads 922 may be on adjacent sides of the module.

The ability of the cells 900 and 910 to be sized to fit into the modules 920 is in part due to the ability to customize the sizes of the cells. In one embodiment, the cells in the present invention may be non-silicon based cells such as but not limited to thin-film solar cells that may be sized as desired while still providing a certain total output. For example, the module 20 of the present size may still provide at least about 200 W of power at AM1.5G exposure. Optionally, the module 920 may also provide at least 5 amp of current and at least 35 volts of voltage at AM1.5G exposure. Details of some suitable cells can be found in U.S. patent application Ser. No. 11/362,266 filed Feb. 23, 2006, and Ser. No. 11/207,157 filed Aug. 16, 2005, both of which are fully incorporated herein by reference for all purposes. In one embodiment, cells 910 weigh less than 14 grams and cells 900 weigh less than 7 grams. Optionally, total module weight may be less than about 32 kg, optionally less than about 31 kg. Optionally, some embodiments may have module weight of about 30 kg or less. Optionally, some embodiments may have module weight of about 29 kg or less. Optionally, some embodiments may have module weight of about 28 kg or less for the specified size.

Although not limited to the following, the modules of FIGS. 21 and/or 22 may also include other features besides the variations in cell size. For example, the modules may be configured for a landscape orientation and may have connectors 922 that extend from two separate exit locations, each of the locations located near the edge of each module. Optionally, each of the modules 920 may also include a border 930 around all of the cells to provide spacing for weatherproof striping, moisture barrier tape, or the like.

In one embodiment, the module includes about 3 to about 30 strings of about 3 to about 30 cells in each string, which in total generates about 200 Watts (+/−5%) with more than 2 amperes current at AM1.5G illumination. Some embodiments may generate 5 amperes current or more. Other embodiments may generate 10 amperes current or more. Optionally, the module includes about 10 to about 18 strings of about 5 to about 8 cells in each string, which in total generates about 200 Watts (+/−5%) with more than 2 amperes current at AM1.5G illumination. Optionally, the module includes about 10 to about 18 strings of about 5 to about 8 cells in each string, which in total generates about 140 Watts (+/−5%) with more than 2 amperes current at AM1.5G illumination. Optionally, the module includes about 14 strings of 6 cells which in total generates about 200 Watts (+/−5%) with more than 5 amp current at AM1.5G illumination.

Embodiments herein may also be modified to include one or more of the following. In one embodiment, the module includes one or more thin-film cells sized to an area sufficiently large to generate a current greater than about 2 amperes under AM1.5G illumination and wherein less than about 15% of a top side surface area of the one or more cells comprises of an opaque conductor, irrespective of cell size. Optionally, less than about 10% of a top side surface area of the one or more cells comprises of the opaque conductor. Optionally, less than about 8% of a top side surface area of the one or more cells comprises of the opaque conductor. Optionally, less than about 7.5% of a top side surface area of the one or more cells comprises of the opaque conductor. Optionally, less than about 5% of a top side surface area of the one or more cells comprises of the opaque conductor. Optionally, less than about 2.5% of a top side surface area of the one or more cells comprises of the opaque conductor. Optionally, the module includes one or more thin-film cells sized to an area sufficiently large to generate a current greater than about 5 amperes under AM1.5G illumination. Optionally, one or more cells have an active area of at least 97.5% of total cell size. Optionally, one or more cells have an active area of at least 95% of total cell size. This may be achieved by selection of finger pattern, finger width, and size of traces as shown in FIG. 20. Optionally, one or more cells have an active area of at least 92.5% of total cell size. Optionally, one or more cells have an active area of at least 90% of total cell size. Optionally, one or more cells have an active area of at least 85% of total cell size. Optionally, the bottom electrode of one cell has an area of sufficient ampacity to carry current from an upstream cell electrically coupled to the cell. Optionally, the bottom electrode has sufficient thickness of metal foil to carry at least 5 amperes of current. Optionally, the bottom electrode has sufficient thickness of aluminum foil to carry at least 5 amperes of current. Optionally, the bottom electrode has sufficient thickness of aluminum foil of about 25 to about 125 microns to carry at least 5 amperes of current. Optionally, the backplane may be in the range of about 1 mil to about 5 mils. Optionally, in some embodiments, the thickness may be in the range of about 0.5 mil to about 20 mil, about 1 mil to about 10 mil, or about 2 mil to about 6 mil. In one embodiment, the thickness of a copper foil may be about 0.8 mils. Optionally, some alternative embodiments may use foils thicker than 20 mils. Preferably, the electrical path between the filled via and the bottom electrode or backplane is a clean contact without resistive losses. Oxides such as that of aluminum form very quickly and are highly electrically resistive. The surface contact between such a foil is desirably without such electrically resistive material between the filled via and the backside foil at the select areas where they contact. Thus, the foil is either cleaned at these areas and joined to the vias in a inert atmosphere where contamination or oxidation does not occur. Optionally, the foil may be thinly coated by a second layer of material that does not corrode to form electrically resistive material. The layer of second material may have a thickness in the range of about 5 to about 50 nanometers. The layer of second material may have a thickness in the range of about 1 to about 200 nanometers. Optionally, the layer of second material may have a thickness in the range of about 200 to about 2000 nanometers. By way of nonlimiting example, the second material may be comprised of copper, copper alloy, copper oxide, nickel, gold, silver, silver oxide, tin, chromium, steel, or alloys thereof. These may be applied over only areas where the filled vias connected to the backside or they may be configured to cover the entire side of the foil.

Embodiments herein may also be modified to include one or more of the following. The bottom electrode may be comprised of a sputtered material is deposited directly on a highly conductive foil. Optionally, a thin-film bottom electrode (such as but not limited to an Mo layer) is directly deposited on top of a highly conductive (Copper, Aluminum, Bronze, metal, or other metal coated) foil . . . to achieve current-carrying capacity for that end of the cell too. The latter differentiates some embodiments from thin-film-on-foil embodiments where the foil is a plastic (or an insulator or a bare stainless steel foil with insufficient current-carrying capacity). Optionally, thin-film bottom electrode of one cell is laser welded to a highly conductive backside foil of another cell to achieve current-carrying capacity between from one cell to another cell. Optionally for each cell, a thin-film bottom electrode of one cell is electrically coupled to a highly conductive backside foil of another cell to achieve current-carrying capacity between from one cell to another cell. Optionally, for each cell, a thin-film bottom electrode is directly deposited or placed on top of a highly conductive foil to achieve current-carrying capacity between from one cell to another cell. Optionally, resistive losses in a transparent conductor of the one or more cells is minimized through the use of vias filled with electrical conductors, wherein the vias are dispersed over the one or more cells to couple the transparent conductor to a high ampacity, bulk electrical conductor below a photovoltaic absorber layer in the one or more cells. Optionally, the vias are distributed in a regular, repeating pattern. Optionally, the vias have fingers that are distributed in a regular, repeating pattern. Optionally, the vias are distributed in an irregular pattern. Optionally, the vias have fingers that are distributed in an irregular pattern. Optionally, the vias have depth between about 10 microns to about 300 microns. Optionally, the vias have depth between about 150 microns to about 250 microns.

Embodiments herein may also be modified to include one or more of the following. In one embodiment, the module provides the electrical output without using monolithically integrated photovoltaic cells. Optionally, the solar module includes only a single photovoltaic cell. Optionally, the single photovoltaic cell has an area of 0.5 m2 or more. Optionally, the single photovoltaic cell has an area of 1 m2 or more. Optionally, the single photovoltaic cell has an area of 2 m2 or more. Optionally, the single photovoltaic cell has an area of 3 m2 or more. Optionally, resistive losses encountered in the transparent conductor is less than 5% before charge is collected by a conductive finger or conductive via. Optionally, resistive losses encountered in the transparent conductor is less than 3% before charge is collected by a conductive finger or conductive via. Optionally, the module includes about 1 to about 200 cells, wherein the module generates about 200 Watts (+/−5%) at more than 2 amperes current when under AM1.5G illumination. Optionally, the module includes about 1 to about 168 cells. Optionally, the module includes about 1 to about 100 cells. Optionally, the module includes about 42 to about 84 cells. Optionally, the module includes about 1 to about 200 cells, wherein the module generates about 140 Watts (+/−5%) at more than 2 amperes current when under AM1.5G illumination. Optionally, the module includes about 1 to about 168 cells. Optionally, the module includes about 1 to about 100 cells. Optionally, the module includes about 42 to about 84 cells. Optionally, the module includes about 3 to about 30 strings of about 3 to about 30 cells in each string, which in total generates about 200 Watts (+/−5%) with more than 2 amperes current at AM1.5G illumination. Optionally, the module includes about 10 to about 18 strings of about 5 to about 8 cells in each string, which in total generates about 200 Watts (+/−5%) with more than 2 amperes current at AM1.5G illumination. Optionally, the module includes about 10 to about 18 strings of about 5 to about 8 cells in each string, which in total generates about 140 Watts (+/−5%) with more than 2 amperes current at AM1.5G illumination. Optionally, the module includes about 14 strings of 6 cells which in total generates about 200 Watts (+/−5%) with more than 5 amperes current at AM1.5G illumination. Optionally, the module includes about 14 strings of 6 cells which in total generates about 140 Watts (+/−5%) with more than 5 amperes current at AM1.5G illumination. Optionally, the module has electrical connectors for wiring the module in a landscape configuration. Optionally, the module has electrical connectors for wiring the module in a portrait configuration. Optionally, the absorber layer comprises of an inorganic material. Optionally, the absorber layer comprises of an organic material. Optionally, the module comprises a flexible module. Optionally, the module comprises a glass-glass module. Optionally, the module comprises a glass-foil module.

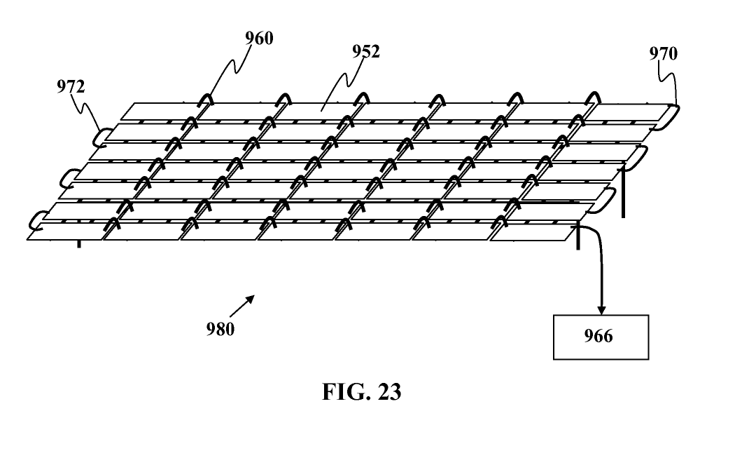

FIG. 23 shows yet another embodiment wherein each row of modules 952 is coupled in series and then the entire row is then coupled in series at one end by connector 970 to an adjacent row of modules 952. Connectors 972 may be used at the other end of the row to serially connect modules 952 to the next row of modules. All of the modules may be coupled in series and then finally coupled to an inverter 966. Alternatively, one or more rows may be coupled in series, but not all the rows are electrically coupled together. In this manner, groups of rows are serially connected, but not all the modules in the entire installation are serially connected together. It should be understood that by way of nonlimiting example, the connectors 960 between modules may be on the top side, bottom side, side-to-side, or other combinations of orientations relative the module top surface.

FIG. 23 shows that multiple strings 980 of modules 952 may be coupled together to a single inverter at a single location. Although not limited to the following, inverters are generally rated to handle much more capacity than the output of a group 980 of modules 952. Hence, it is more efficient to couple multiple groups 980 of modules 952 to a single inverter. This minimizes costs spent on inverters and more fully utilizes equipment deployed at the installation site. Cabling is used to couple the groups 980 to the inverter 966. Optionally, other embodiments may have a single inverter for each module string.

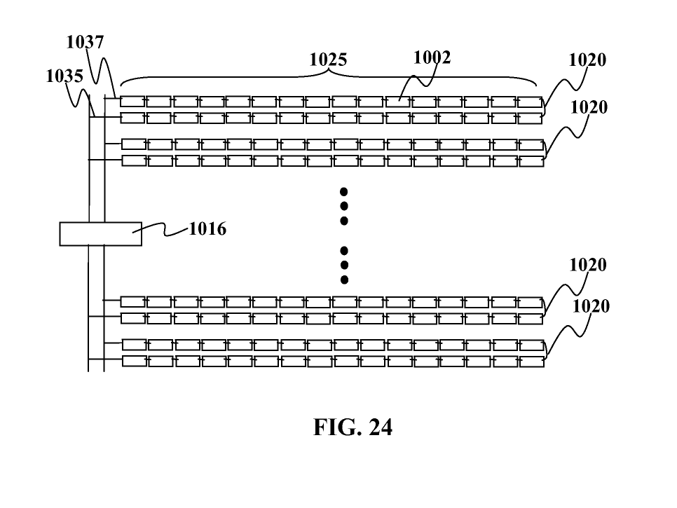

FIG. 24 shows how modules 1002 and connectors 1020 can be positioned to substantially reduce the amount of wiring used to connect the modules to an inverter 1016. In conventional PV systems, modules have external cables in the total length per module of at least the long side of the module, and they typically have internal wiring in the amount of at least the short side of the module (in order to bring current from internal strings back to the middle of the module where the traditional junction box is located). A conventional PV system for a row similar that of row 1025 would use more than 38.2 M*(27+16*7) per row in module external/internal DC wiring or more than 1986 m in additional cabling for each 100 kW unit (which for embodiments using modules 1002 is 832 modules [32*26]). The present embodiment in FIG. 24 uses only about 140 m in total system DC wiring for 832 modules compared to 3.4 km of total system DC wiring used in a conventional system. Additionally, voltage mismatch issued are avoided which arise in conventional systems due to differential resistive voltage drops over variably long DC cable form the various homerun connections of different length in conventional deployments, wherein the correction of which tends to introduce significant on-site engineering cost and overhead. FIG. 24 shows that by eliminating traditional junction boxes, using direct module-to-module interconnections/connectors at the left and right edges of each module 1002, and configuring the modules to be two rows coupled in a U-configuration (and keeping row connectors at the same end for all rows), the wiring is significantly simplified. Connections to the inverter 1016 from each row 1025 are based on short connectors 1035 and 1037 which couple to wiring leading to the inverter.

To maximize the number of modules that can be delivered to these installations site, the modules may be sized in length between about 1660 mm to about 1666 mm and width of about 700 mm to about 706 mm. The modules may be framed or unframed. More details of the suitable size may be found copending U.S. patent application Ser. No. 11/538,039 (Attorney Docket No. NSL-096A) filed Oct. 2, 2006 and fully incorporated herein by reference for all purposes.

In one embodiment, the system includes a plurality of thin film solar modules electrically coupled in series; wherein total system voltage of the plurality of solar modules in series does not exceed about 1000V; wherein total system current is about 2 amperes or more; wherein total system power output is about 2000 watts or more due to the high current output of the thin film modules. Optionally, total system power output is about 3000 watts or more. Optionally, total system power output is about 5000 watts or more. Optionally, total system power output is about 10000 watts or more. In one embodiment, a module string of thin-film base modules includes between about 15 modules to about 22 modules. In another embodiment, a module string of thin-film base modules includes between about 10 modules to about 60 modules. Optionally, the total voltage of the plurality of solar modules in series does not exceed about 600V.

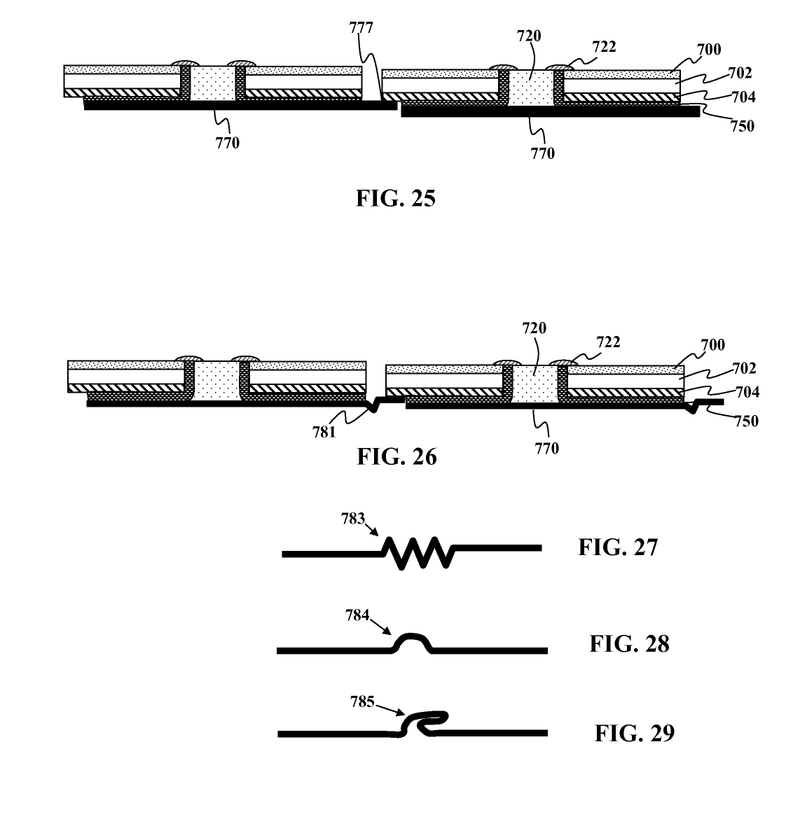

Referring now to FIG. 25, a still further embodiment of the present invention will now be described. The electrically conductive material 124 filling the vias shown in FIG. 1 is electrically coupled to an electrically conductive backplane 108. The backplane 108 acts as a backside electrode and carries electrical charge. Unfortunately, the electrical conductivity of the backplane 108 may be significantly impacted by the quality of the electrical connection between the via filling material 124 and the interface with backplane 108. The quality of the electrical connection is dependent in part on any corrosion, contamination, sulfide, or oxide buildup that may have formed on the contact surface of backplane 108. This is a particular issue for an aluminum backplane 108 wherein aluminum oxide forms very rapidly (i.e. within a minute or so) in an ambient atmosphere. Because aluminum oxide is an electrically resistive material, the formation of aluminum oxide over the aluminum backplane 108 is problematic as it reduces the electrical conductivity of the backplane 108 due to increased electrical resistance at the junction of material 124 and backplane 108. It should be understood that backplanes comprised of steel or other metallic materials prone to oxidation may also have this electrical conductivity issue, which may significantly impact the efficiency of the entire photovoltaic device.

The embodiment of FIG. 23 also shows the layout and connectivity of the system block. In this embodiment, the low-voltage, high voltage “utility modules” are directly interconnected via two opposing exit connectors they each have on opposite corners of the module in landscape mode, without the use of additional cabling as common in conventional modules and systems (there is also no extra module-internal wiring). The dimensions and the design of the modules are optimized with respect to inverter characteristics and with respect to efficient shipping in standard international shipping containers. Using an ultra-low cost non-pervasive mounting system developed as part of this project, the modules are tilted to optimize performance and manage wind loads. The non-invasive mounting system specifically exploits the differential wind loads in the center versus the periphery of the system area in order to arrive at its cost structure. A central inverter is used whose efficiency has been specifically tuned. Total-system wiring, including module-internal wiring, module-external cables, module-to-module cabling, and module-to-inverter cabling, is minimal.

In the present embodiment, Directly interconnected strings of low-voltage two-exit modules of size 166×70 cm in landscape orientation, 10-30 degree performance-tilted; Conergy IPG 110 KW inverter; low-cost non-penetrating wind-tunnel optimized mounting; minimal DC cabling. A nominal-100 kW deployment consists of 832 (=32*26) modules. Optionally, other embodiments may use size 197×107 cm modules, 10-30 degree performance-tilted on supports.

In conventional PV systems, modules have external cables in the total length per module of at least the long side of the module; and they typically have internal wiring in the amount of at least the short side of the module (in order to bring current from internal strings back to the middle of the module). For a row shown in FIG. 2, a conventional PV system would therefore use more than 38.2 m (27+16*0.7) per row in module-external/internal DC wiring, or more than 1986 m in additional cabling for each 100 kW unit. In addition, due to modules generally having voltages not optimized for large-scale applications (relative to their systems voltage and inverter requirements), even more cabling tends to be required: e.g. for every seven series-interconnected modules with a high voltage module, a connection to homerun cabling is necessary, thus requiring additional cable (here as much as 1404 m) and even more for large-scale deployments with longer rows. Our system design proposed here with our components requires only 140 m in total-system DC wiring compared with 3.4 km of total-system DC wiring used in a conventional system. Perhaps even more importantly, voltage mismatch issues are avoided which occur due to differential resistive voltage drops over variably long DC cables from the various homerun connections, the correction of which tends to introduce significant additional on-site engineering cost and overhead.

Referring now to FIG. 25, yet another embodiment of the present invention will now be described. This shows that the backside conductor 770 of one cell may be electrically connected to the bottom electrode 704 of another photovoltaic cell. The backside conductor 770 of one cell may be electrically connected to the bottom electrode 704 at location 777. The backside conductor 770 of one cell may be electrically connected to the bottom electrode 704 by various methods including but not limited to laser welding, ultrasonic welding, welding, soldering, ultrasonic soldering, laser soldering, spot welding, or other joining technique that allows for electronic connection. The joining may occur from a side, top, and/or the underside of the cells. FIG. 25 also shows that the backside conductor 770 may be positioned to be offset relative to the layer 704. This offset allows backside conductor 770 to extend out beyond the edge of the cell and this also exposes a portion of layer 704 to allow for electrical interconnection at location 777.

FIG. 26 shows that in another embodiment, the backside connector 779 may be configured to have a strain relief element. In this embodiment, the strain relief element comprises of a kink or bend 781 that allows for some flexibility to prevent the connection at 777 from taking all the load from any stress or strain between cells.

FIGS. 27-29 shows that in other embodiments, the strain relief element may be a wave element 783, a rounded portion 784, or a loop 785. Optionally, other shaped elements may be used. These shapes may be in the vertical and/or horizontal dimension and are not limited to merely vertical shapes. Some maybe shapes only in the horizontal dimension and do not form out-of-plane deflections. Thus deformations are only formed in plane.

While the invention has been described and illustrated with reference to certain particular embodiments thereof, those skilled in the art will appreciate that various adaptations, changes, modifications, substitutions, deletions, or additions of procedures and protocols may be made without departing from the spirit and scope of the invention. For example, with any of the above embodiments, the use of spray on insulating material may also be combined with other printing techniques to apply various layers of material to the solar cell. In one embodiment, insulation material may be provided by spray-on technique while the filling of the via may occur by printing, or vice versa. It should be understood that the methods and devices of this invention may be adapted for use with other devices with vias extending through one or more layers of such devices. For ease of illustration, the vias herein are shown as being circular in shape, but in other embodiments, they may be square, rectangular, polygonal, oval, triangular, other shaped, or combinations of the foregoing. It should also be understood that any of the spraying, air impringement, or coating techniques herein may be configured for use in a roll-to-roll type substrate or foil handling system.

Optionally, one embodiment of the present invention uses a layer of a second material to address the electrical conductivity issue over the backside electrical conductor. In one embodiment, the layer may be comprised of an electrically conductive material on one side of the backplane that contacts the material in the vias. Optionally, some embodiments of the invention may have conductive material on both sides of the backplane 108. The layer 230 of the second material on the backplane 108 may be comprised of one or more of the following: copper, nickel, tin, silver, platinum, gold, palladium, chromium, vanadium, tungsten, molybdenum, titanium nitride, tantalum nitride, tungsten nitride, silicon nitride, other conductive metal nitrides, conductive metal carbides such as but not limited to, tantalum carbide, zirconium carbide, hafnium carbide, conductive metal oxides, heavily doped semiconductors, oxygen rich titanium oxide (TiO7), combinations thereof, or their alloys.

Referring now to FIG. 26, it is shown that the surface of backplane 108 is not necessarily covered entirely by layer 230. FIG. 4 shows one embodiment wherein the coverage is partial and defined as a plurality of linear strips 240. The strips 240 may be as wide as the vias. Optionally, the strips 240 are narrower than the vias, but still provide an area of good electrical contact. These strips 240 allow for reduced material usage as coverage of areas without the vias is minimized Curved strips, angled strips, or strips of other geometric configurations may be adapted for use with the present invention.

Additionally, concentrations, amounts, and other numerical data may be presented herein in a range format. It is to be understood that such range format is used merely for convenience and brevity and should be interpreted flexibly to include not only the numerical values explicitly recited as the limits of the range, but also to include all the individual numerical values or sub-ranges encompassed within that range as if each numerical value and sub-range is explicitly recited. For example, a size range of about 1 nm to about 200 nm should be interpreted to include not only the explicitly recited limits of about 1 nm and about 200 nm, but also to include individual sizes such as 2 nm, 3 nm, 4 nm, and sub-ranges such as 10 nm to 50 nm, 20 nm to 100 nm, etc. . . .

The publications discussed or cited herein are provided solely for their disclosure prior to the filing date of the present application. Nothing herein is to be construed as an admission that the present invention is not entitled to antedate such publication by virtue of prior invention. Further, the dates of publication provided may be different from the actual publication dates which may need to be independently confirmed. All publications mentioned herein are incorporated herein by reference to disclose and describe the structures and/or methods in connection with which the publications are cited. For example, U.S. patent application Ser. No. 11/039,053, filed Jan. 20, 2005 and U.S. patent application Ser. No. 11/207,157 filed Aug. 16, 2005, are fully incorporated herein by reference for all purposes. U.S. Provisional Patent Application Ser. No. 60/781,165 entitled HIGH-EFFICIENCY SOLAR CELL WITH INSULATED VIAS filed on Mar. 10, 2006, U.S. Provisional Application 60/989,114 filed Nov. 19, 2007, and U.S. patent application Ser. No. 11/278,645 filed on Apr. 4, 2006 are also fully incorporated herein by reference for all purposes.

While the above is a complete description of the preferred embodiment of the present invention, it is possible to use various alternatives, modifications and equivalents. Therefore, the scope of the present invention should be determined not with reference to the above description but should, instead, be determined with reference to the appended claims, along with their full scope of equivalents. Any feature, whether preferred or not, may be combined with any other feature, whether preferred or not. In the claims that follow, the indefinite article “A”, or “An” refers to a quantity of one or more of the item following the article, except where expressly stated otherwise. The appended claims are not to be interpreted as including means-plus-function limitations, unless such a limitation is explicitly recited in a given claim using the phrase “means for.”

1. A high current photovoltaic apparatus comprising. one or more thin-film cells sized to an area sufficiently large to generate a current greater than about 2 amperes under AM1.5G illumination and wherein less than about 15% of a top side surface area of the one or more cells comprises of an opaque conductor, irrespective of cell size.

2-9. (canceled)

10. The apparatus of claim 1 wherein less than about 5% of a top side surface area of the one or more cells comprises of the opaque conductor.

11. (canceled)

12. The apparatus of claim 1 wherein module includes one or more thin-film cells sized to an area sufficiently large to generate a current greater than about 5 amperes under AM1.5G illumination.

13-17. (canceled)

18. The apparatus of claim 12 wherein the bottom electrode of one cell has an area of sufficient ampacity to carry current from an upstream cell electrically coupled to the cell.

19. The apparatus of claim 12 wherein the bottom electrode has sufficient thickness of metal foil to carry at least 5 amperes of current.

20. The apparatus of claim 12 wherein the bottom electrode has sufficient thickness of aluminum foil to carry at least 5 amperes of current.

22. The apparatus of claim 12 wherein electrical connection between a filled via in the cell and the bottom electrode is without electrical losses at a junction therebetween.

23. The apparatus of claim 12 wherein electrical connection between a filled via in the cell and the bottom electrode is without electrically resistive oxide therebetween.

24. The apparatus of claim 12 wherein for each cell, a thin-film bottom electrode of one cell is laser welded to a highly conductive backside foil of another cell to achieve current-carrying capacity between from one cell to another cell.

25. The apparatus of claim 12 wherein for each cell, a thin-film bottom electrode of one cell is electrically coupled to a highly conductive backside foil of another cell to achieve current-carrying capacity between from one cell to another cell.

26. The apparatus of claim 12 wherein for each cell, a thin-film bottom electrode is directly deposited or placed on top of a highly conductive foil to achieve current-carrying capacity between from one cell to another cell.

27. The apparatus of claim 12 wherein resistive losses in a transparent conductor of the one or more cells is minimized through the use of vias filled with electrical conductors, wherein the vias are dispersed over the one or more cells to couple the transparent conductor to a high ampacity, bulk electrical conductor below a photovoltaic absorber layer in the one or more cells.

28-31. (canceled)

32. The apparatus of claim 27 wherein the vias have depth between about 10 microns to about 300 microns.

33. The apparatus of claim 27 wherein the vias have depth between about 150 microns to about 250 microns.

34. The apparatus of claim 12 wherein a ratio of opaque conductor area to exposed active area photovoltaic material is between about 1:9 to about 1:39.

35. The apparatus of claim 12 wherein increased cell size does not substantially increase cell shading due to increased ampacity of a backside electrical conductor to handle at least 5 amperes of current.

36. The apparatus of claim 1 wherein module includes one or more thin-film cells, wherein each of the one or more solar cells includes a backside electrical conductor having an average thickness of about 50 to about 100 microns.

37. The apparatus of claim 1 wherein module includes one or more thin-film cells, wherein each of the one or more solar cells includes a backside electrical conductor having an average thickness of about 100 to about 800 microns.

38-53. (canceled)

54. The apparatus of claim 1 wherein resistive losses encountered in the transparent conductor is less than 5% before charge is collected by a conductive finger or conductive via.

55. The apparatus of claim 1 wherein resistive losses encountered in the transparent conductor is less than 3% before charge is collected by a conductive finger or conductive via.

56-115. (canceled)
